(19) United States
(12) Patent Application Publication
(10) Pub. No.: US 2024/0357871 A1
(43) Pub. Date: Oct. 24, 2024

(54) DISPLAY DEVICE AND METHOD OF FABRICATING THE SAME

(71) Applicant: Samsung Display Co., LTD., Yongin-si (KR)

(72) Inventors: Hyun Eok SHIN, Yongin-si (KR); Joon Yong PARK, Yongin-si (KR); Dong Min LEE, Yongin-si (KR)

(73) Assignee: Samsung Display Co., LTD., Yongin-si (KR)

(21) Appl. No.: 18/521,142

(22) Filed: Nov. 28, 2023

(30) Foreign Application Priority Data
Apr. 19, 2023 (KR) 10-2023-0051252

(51) Int. Cl. H10K 59/122; H10K 59/80; H10K 71/60

(52) U.S. Cl. CPC H10K 59/122; H10K 59/80522; H10K 71/60; H10K 2102/102; H10K 2102/103

(57) ABSTRACT

A display device includes anode electrodes spaced apart, a bank structure surrounding the anode electrodes, and including openings, a capping layer on the anode electrode, electrically connected thereto, and having at least a portion spaced apart from the anode electrodes, an inorganic insulating layer on the capping layer within the openings and exposing a portion of an upper surface of the capping layer, light emitting layers each on the capping layer and having a portion contacting a side surface of the bank structure, cathode electrodes on the light emitting layers and having a portion contacting the side surface of the bank structure, and auxiliary common electrodes on the cathode electrodes and having a portion disposed on the bank structure. The bank structure includes first and second bank layers having different material, and the second includes a tip protruding more than the first bank layer.

### CROSS-REFERENCE TO RELATED APPLICATION(S)

This application claims priority to and benefits of Korean Patent Application No. 10-2023-0051252 under 35 U.S.C. 119, filed on Apr. 19, 2023 in the Korean Intellectual Property Office, the entire contents of which are herein incorporated by reference.

### BACKGROUND

### 1. Technical Field

The disclosure relates to a display device and a method of fabricating the same.

### 2. Description of the Related Art

As information society develops, demand for display devices for displaying images is increasing in various forms. For example, display devices have been applied to various electronic devices such as smartphones, digital cameras, laptop computers, navigation devices, and smart televisions. Display devices may be flat panel display devices such as liquid crystal display devices, field emission display devices, or organic light emitting display devices. Among flat panel display devices, light emitting display devices may include a light emitting element in which each of the pixels of a display panel may emit light by itself, thereby displaying an image without a backlight unit providing the light to the display panel.

### SUMMARY

Aspects of the disclosure provide a display device in which light emission efficiency of a light emitting element is improved by forming separated light emitting elements for each light emitting area without a mask process and including an optical compensation structure.

However, aspects of the disclosure are not restricted to those set forth herein. The above and other aspects of the disclosure will become more apparent to one of ordinary skill in the art to which the disclosure pertains by referencing the detailed description of the embodiments given below.

In the display device according to an embodiment, a gap between a cathode electrode and an anode electrode of the light emitting element may be greater than a thickness of a light emitting layer. Since a capping layer forming an equipotential with the anode electrode is disposed on a dummy pattern, the light emitting element of the display device may have an appropriate optical thickness and a thin light emitting layer, so that driving voltage characteristics thereof may be excellent.

According to an embodiment of the disclosure, a display device may include a plurality of anode electrodes disposed to be spaced apart from each other on a substrate, a bank structure disposed on the substrate, disposed to surround the plurality of anode electrodes, and including a plurality of openings overlapping the plurality of anode electrodes, a capping layer disposed on the plurality of anode electrodes, electrically connected to the plurality of anode electrodes, and having at least a portion spaced apart from the plurality of anode electrodes, an inorganic insulating layer disposed on the capping layer within the plurality of openings of the bank structure and exposing a portion of an upper surface of the capping layer, a plurality of light emitting layers each disposed on the capping layer and having a portion contacting a side surface of the bank structure, a plurality of cathode electrodes disposed on the plurality of light emitting layers and having a portion contacting the side surface of the bank structure, and a plurality of auxiliary common electrodes disposed on the plurality of cathode electrodes and having a portion disposed on the bank structure. The bank structure may include a first bank layer, and a second bank layer disposed on the first bank layer, including a material different from a material of the first bank layer, and including a tip protruding more than the first bank layer, and the plurality of auxiliary common electrodes directly contact a side surface of the first bank layer and the second bank layer.

The display device may further include a dummy pattern disposed between the plurality of anode electrodes and the capping layer.

The first bank layer and the dummy pattern may include a same material, and the second bank layer may include a metal material.

Each of the dummy pattern and the first bank layer may include a transparent insulating material, and the second bank layer may include titanium (Ti).

The dummy pattern may have a thickness greater than a thickness of the plurality of anode electrodes but smaller than a thickness of the first bank layer.

An area of the dummy pattern may be smaller than an area of the plurality of anode electrodes, and the capping layer may directly contact a portion of the plurality of anode electrodes that do not overlap the dummy pattern.

The dummy pattern may include silicon oxide, the first bank layer may include aluminum (Al), and the second bank layer may include titanium (Ti).

The capping layer may be disposed to cover an outer surface of the dummy pattern.

A portion of the plurality of light emitting layer may be directly disposed on the side surface of the first bank layer, and the plurality of cathode electrodes may cover the plurality of light emitting layers and a portion of the plurality of cathode electrodes may be disposed directly on the side surface of the first bank layer.

The plurality of light emitting layers and the plurality of cathode electrodes may be spaced apart from the second bank layer.

The inorganic insulating layer may be disposed to cover a side surface of the plurality of anode electrodes, and at least a portion of the inorganic insulating layer may be spaced apart from the second bank layer.

A portion of the plurality of auxiliary common electrodes may be disposed on a lower portion of the tip of the second bank layer.

The capping layer may include at least one of ITO, IZO, and ITZO, and the plurality of auxiliary common electrodes may include at least one of ITO, IZO, and TiN.

The display device may further include a capping pattern disposed on the second bank layer and including a same material as the capping layer, an organic pattern disposed on the capping pattern and including a same material as the plurality of light emitting layers, and an electrode pattern disposed on the organic pattern and including a same material as the plurality of cathode electrodes, wherein a portion of the plurality of auxiliary common electrodes may be directly disposed on the electrode pattern.

The display device may further include an inorganic layer disposed on the plurality of auxiliary common electrodes.

According to an embodiment of the disclosure, a method of fabricating a display device may include forming a plurality of anode electrodes spaced apart from each other on a substrate, a first bank material layer disposed on the plurality of anode electrodes and the substrate, and a second bank material layer, forming a dummy pattern disposed on the plurality of anode electrodes by etching the first bank material layer and the second bank material layer, and forming an opening overlapping the plurality of anode electrodes, forming a capping layer on the dummy pattern and forming an inorganic insulating layer disposed on the capping layer and exposing a portion of an upper surface of the capping layer, forming a light emitting layer and a cathode electrode on the capping layer and the inorganic insulating layer, forming an auxiliary common electrode disposed on the cathode electrode and disposed on a sidewall of the opening and the second bank material layer, and an inorganic layer disposed on the auxiliary common electrode, and etching and removing a portion of the auxiliary common electrode and the inorganic layer disposed on the second bank material layer.

In the forming of the opening, the second bank material layer may have a tip protruding more than the first bank material layer.

The light emitting layer and the cathode electrode may partially contact the first bank material layer on the sidewall within the opening, and the auxiliary common electrode may directly contact the first bank material layer and the second bank material layer.

The dummy pattern may include a same material as the first bank material layer, and have a thickness smaller than a thickness of the first bank material layer and an area smaller than an area of the plurality of anode electrodes.

The capping layer may partially directly contact the plurality of anode electrodes.

Effects of the embodiments are not restricted to those set forth herein. Effects of the embodiments will become more apparent to one of ordinary skill in the art to which the embodiments pertain by referencing the disclosure.

### BRIEF DESCRIPTION OF THE DRAWINGS

The above and other aspects and features of the disclosure will become more apparent by describing in detail embodiments thereof with reference to the attached drawings, in which:

FIG. 1 is a schematic perspective view of an electronic device according to an embodiment;

FIG. 2 is a schematic perspective view illustrating a display device included in the electronic device according to an embodiment;

FIG. 3 is a schematic cross-sectional view of the display device of FIG. 2 viewed from a side;

FIG. 4 is a schematic plan view illustrating a display layer of the display device according to an embodiment;

FIG. 5 is a schematic plan view illustrating an arrangement of light emitting areas and color filters in a display area of the display device according to an embodiment;

FIG. 6 is a schematic cross-sectional view illustrating a portion of the display device according to an embodiment;

FIG. 7 is an enlarged schematic view illustrating a first light emitting area of FIG. 6;

FIGS. 8 to 19 are schematic cross-sectional views sequentially illustrating a display area during a process of fabricating a display device according to an embodiment; and.

FIG. 20 is a schematic cross-sectional view illustrating a portion of a display device according to another embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, sizes, thicknesses, ratios, and dimensions of the elements may be exaggerated for ease of description and for clarity. Like numbers refer to like elements throughout.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean any combination including “A, B, or A and B.” The terms “and” and “or” may be used in the conjunctive or disjunctive sense and may be understood to be equivalent to “and/or.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

The term “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as “not overlapping” or to “not overlap” another element, this may include that the elements are spaced apart from each other, offset from each other, or set aside from each other or any other suitable term as would be appreciated and understood by those of ordinary skill in the art.

It will also be understood that when a layer is referred to as being “on” another layer or substrate, it can be directly on the other layer or substrate, or intervening layers may also be present.

It will be understood that when an element (or a region, a layer, a portion, or the like) is referred to as “being on”, “connected to” or “coupled to” another element in the specification, it can be directly disposed on, connected or coupled to another element mentioned above, or intervening elements may be disposed therebetween.

It will be understood that the terms “connected to” or “coupled to” may include a physical and/or electrical connection or coupling.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

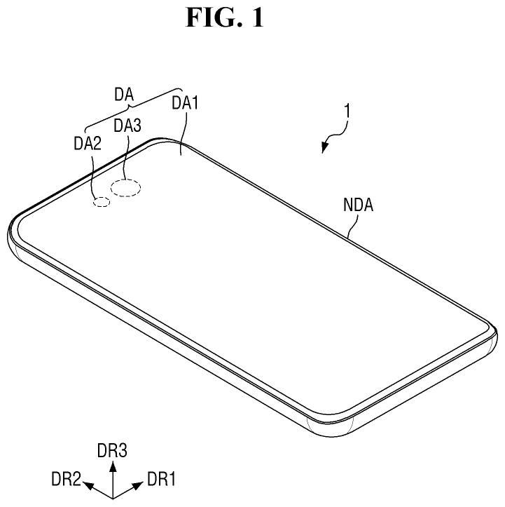

FIG. 1 is a schematic perspective view of an electronic device according to an embodiment.

Referring to FIG. 1, an electronic device 1 displays a moving image or a still image. The electronic device 1 may refer to any electronic device that provides a display screen. For example, electronic device 1 may include televisions, laptop computers, monitors, billboards, Internet of Things devices, mobile phones, smartphones, tablet personal computers (PCs), electronic watches, smartwatches, watch phones, head mounted displays, mobile communication terminals, electronic notebooks, electronic books, portable multimedia players (PMPs), navigation, game consoles, digital cameras, camcorders, and the like that provide the display screen.

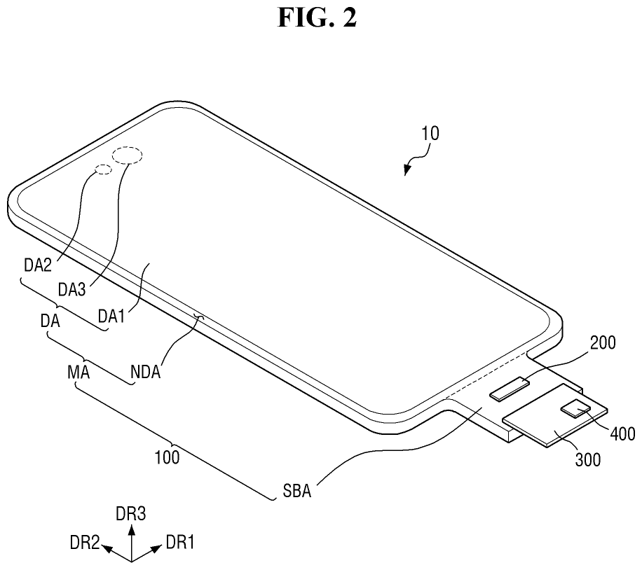

The electronic device 1 may include a display device (“10” in FIG. 2) that includes a display screen. Examples of the display device may include an inorganic light emitting diode display device, an organic light emitting display device, a quantum dot light emitting display device, a plasma display device, and a field emission display device. Hereinafter, it is illustrated that an organic light emitting diode display device is used as an example of the display device, but the disclosure is not limited thereto and may also be applied to other display devices as long as the same technical aspects are applicable thereto.

A shape of the electronic device 1 may be variously changed. For example, the electronic device 1 may have a shape such as a rectangle with a long width, a rectangle with a long length, a square, a quadrangle with rounded corners (vertices), other polygons, or a circle. A shape of a display area DA of the electronic device 1 may also be similar to an overall shape of the electronic device 1. In FIG. 1, the electronic device 1 having a rectangular shape with a long length in a second direction DR2 is illustrated.

The electronic device 1 may include a display area DA and a non-display area NDA. The display area DA is an area in which a screen may be displayed, and the non-display area NDA is an area in which a screen may not be displayed. The display area DA may also be referred to as an active area, and the non-display area NDA may also be referred to as a non-active area. The display area DA may generally occupy the center of the electronic device 1.

The display area DA may include a first display area DA1, a second display area DA2, and a third display area DA3. The second display area DA2 and the third display area DA3, which may be areas in which components for adding various functions to the electronic device 1 are disposed, may correspond to component areas.

FIG. 2 is a schematic perspective view illustrating a display device included in the electronic device according to an embodiment.

Referring to FIG. 2, the electronic device 1 according to an embodiment may include a display device 10. The display device 10 may provide a screen displayed by the electronic device 1. The display device 10 may have a planar shape similar to that of the electronic device 1. For example, the display device 10 may have a shape similar to a rectangle having a short side in a first direction DR1 and a long side in a second direction DR2. A corner where the short side in the first direction DR1 and the long side in the second direction DR2 meet may be rounded to have a curvature, but is not limited thereto and may also be formed at a right angle. The planar shape of the display device 10 is not limited to the quadrangle, and may be formed similarly to other polygons, circles, and/or ovals.

The display device 10 may include a display panel 100, a display driver 200, a circuit board 300, and a touch driver 400.

The display panel 100 may include a main area MA and a sub-area SBA.

The main area MA may include a display area DA including pixels displaying an image, and a non-display area NDA disposed around the display area DA. The display area DA may include a first display area DA1, a second display area DA2, and a third display area DA3. The display area DA may emit light from light emitting areas or opening areas. For example, the display panel 100 may include a pixel circuit including switching elements, a pixel defining film defining the light emitting areas or the opening areas, and a self-light emitting element.

For example, the self-light emitting element may include at least one of an organic light emitting diode (OLED) including an organic light emitting layer, a quantum dot LED including a quantum dot light emitting layer, an inorganic LED including an inorganic semiconductor, and a micro LED, but is not limited thereto.

The non-display area NDA may be an area outside the display area DA. The non-display area NDA may be defined as an edge area of the main area MA of the display panel 100. The non-display area NDA may include a gate driver (not illustrated) supplying gate signals to gate lines, and fan-out lines (not illustrated) connecting the display driver 200 and the display area DA.

The sub-area SBA may be an area extending from one side of the main area MA. The sub-area SBA may include a flexible material that may be bent, folded, rolled, or the like. For example, in case that the sub-area SBA is bent, the sub-area SBA may overlap the main area MA in a thickness direction (a third direction DR3). The sub-area SBA may include the display driver 200 and a pad portion connected to the circuit board 300. In another embodiment, the sub-area SBA may be omitted, and the display driver 200 and the pad portion may be disposed in the non-display area NDA.

The display driver 200 may output signals and voltages for driving the display panel 100. The display driver 200 may supply data voltages to the data lines. The display driver 200 may supply a power voltage to the power line and may supply a gate control signal to the gate driver. The display driver 200 may be formed as an integrated circuit (IC) and mounted on the display panel 100 by a chip on glass (COG) method, a chip on plastic (COP) method, or an ultrasonic bonding method. For example, the display driver 200 may be disposed in the sub-area SBA, and may overlap the main area MA in the thickness direction by bending of the sub-area SBA. As another example, the display driver 200 may be mounted on the circuit board 300.

The circuit board 300 may be attached onto the pad portion of the display panel 100 using an anisotropic conductive film (ACF). Lead lines of the circuit board 300 may be electrically connected to the pad portion of the display panel 100. The circuit board 300 may be a flexible film such as a flexible printed circuit board, a printed circuit board, or a chip on film.

The touch driver 400 may be mounted on the circuit board 300. The touch driver 400 may be connected to a touch sensing unit of the display panel 100. The touch driver 400 may supply a touch driving signal to touch electrodes of the touch sensing unit, and may sense an amount of change in capacitance between the touch electrodes. For example, the touch driving signal may be a pulse signal having a predetermined or selected frequency. The touch driver 400 may calculate whether an input is made and input coordinates based on the amount of change in capacitance between the touch electrodes. The touch driver 400 may be formed as an integrated circuit (IC).

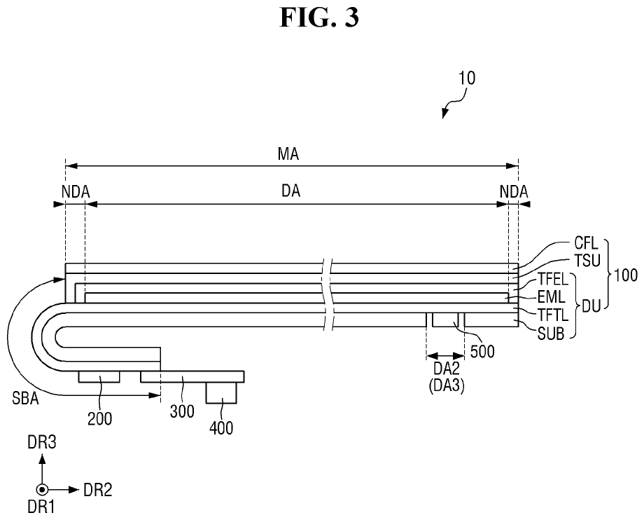

FIG. 3 is a schematic cross-sectional view of the display device of FIG. 2 viewed from a side.

Referring to FIG. 3, the display panel 100 may include a display layer DU, a touch sensing layer TSU, and a color filter layer CFL. The display layer DU may include a substrate SUB, a thin film transistor layer TFTL, a light emitting element layer EML, and a thin film encapsulation layer TFEL.

The substrate SUB may be a base substrate or a base member. The substrate SUB may be a flexible substrate that may be bent, folded, rolled, or the like. For example, the substrate SUB may include a polymer resin such as polyimide (PI), but is not limited thereto. In another embodiment, the substrate SUB may include a glass material and/or a metal material.

The thin film transistor layer TFTL may be disposed on the substrate SUB. The thin film transistor layer TFTL may include thin film transistors constituting a pixel circuit of pixels. The thin film transistor layer TFTL may further include gate lines, data lines, power lines, gate control lines, fan-out lines connecting the display driver 200 and the data lines, and lead lines connecting the display driver 200 and the pad portion. Each of the thin film transistors may include a semiconductor area, a source electrode, a drain electrode, and a gate electrode. For example, in case that the gate driver is formed on one side of the non-display area NDA of the display panel 100, the gate driver may include the thin film transistors.

The thin film transistor layer TFTL may be disposed in the display area DA, the non-display area NDA, and the sub-area SBA. The thin film transistors, the gate lines, the data lines, and the power lines of each of the pixels of the thin film transistor layer TFTL may be disposed in the display area DA. The gate control lines and the fan-out lines of the thin film transistor layer TFTL may be disposed in the non-display area NDA. The lead lines of the thin film transistor layer TFTL may be disposed in the sub-area SBA.

The light emitting element layer EML may be disposed on the thin film transistor layer TFTL. The light emitting element layer EML may include light emitting elements including a first electrode, a second electrode, and a light emitting layer to emit light, and a pixel defining film defining pixels. The light emitting elements of the light emitting element layer EML may be disposed in the display area DA.

In an embodiment, the light emitting layer may be an organic light emitting layer including an organic material. The light emitting layer may include a hole transporting layer, an organic light emitting layer, and an electron transporting layer. In case that the first electrode receives a voltage through the thin film transistor of the thin film transistor layer TFTL and the second electrode receives a cathode voltage, holes and electrons may move to the organic light emitting layer through the hole transporting layer and the electron transporting layer, respectively, and may be combined with each other in the organic light emitting layer to emit light.

In another embodiment, the light emitting element may include a quantum dot light emitting diode including a quantum dot light emitting layer, an inorganic light emitting diode including an inorganic semiconductor, or a micro light emitting diode.

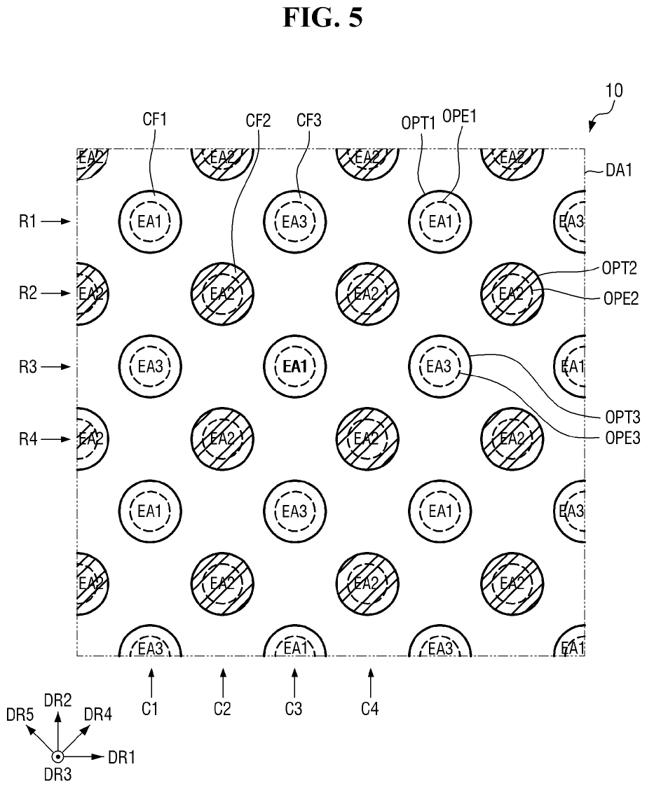

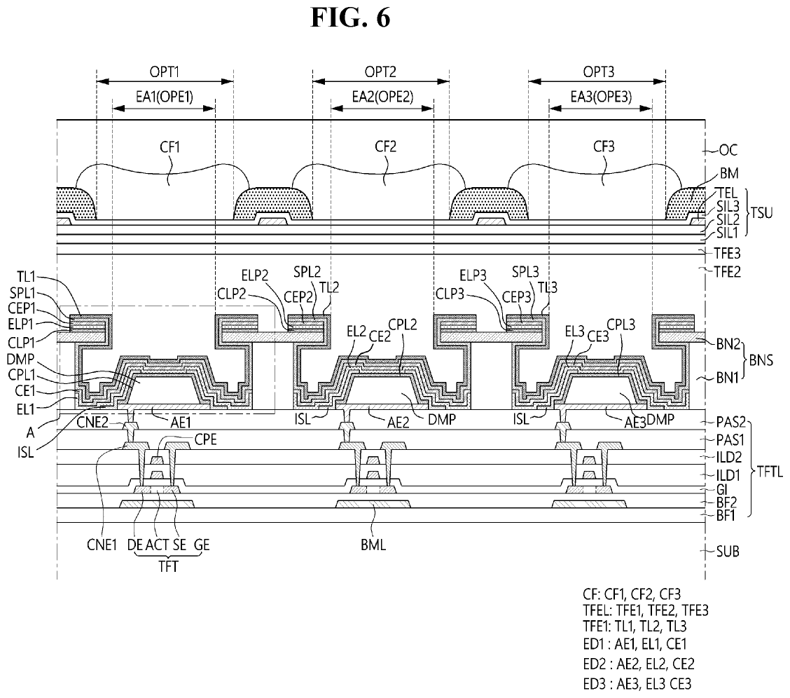

The display device 10 according to an embodiment may include color filters CF (CF1, CF2, and CF3 in FIGS. 5 and 6) disposed on the light emitting elements of the light emitting element layer EML. Each of the color filters CF may selectively transmit light of a specific wavelength and block or absorb light of a different wavelength. The color filters may absorb a portion of light introduced from the outside of the display device 10 to reduce reflected light caused by external light. Therefore, the color filter may prevent color distortion caused by reflection of external light. As the color filters are disposed on the light emitting element, the display device 10 may not require a separate substrate for the color filters. Therefore, the display device 10 may have a relatively small thickness.

The thin film encapsulation layer TFEL may cover an upper surface and side surfaces of the light emitting element layer EML, and may protect the light emitting element layer EML. The thin film encapsulation layer TFEL may include at least one inorganic film and at least one organic film for encapsulating the light emitting element layer EML.

The touch sensing layer TSU may be disposed on the encapsulation layer TFEL. The touch sensing layer TSU may include touch electrodes for detecting a user's touch in a capacitance method, and touch lines connecting the touch electrodes and the touch driver 400. For example, the touch sensing layer TSU may sense the user's touch in a mutual capacitance method or a self-capacitance method.

In another embodiment, the touch sensing layer TSU may be disposed on a separate substrate disposed on the display layer DU. The substrate supporting the touch sensing layer TSU may be a base member that encapsulates the display layer DU.

The touch electrodes of the touch sensing layer TSU may be disposed in a touch sensor area overlapping the display area DA. The touch lines of the touch sensing layer TSU may be disposed in a touch peripheral area overlapping the non-display area NDA.

In some embodiments, the display device 10 may further include an optical device 500. The optical device 500 may be disposed in the second display area DA2 or the third display area DA3. The optical device 500 may emit or receive light in infrared, ultraviolet, and visible light bands. For example, the optical device 500 may be an optical sensor that detects light incident on the display device 10, such as a proximity sensor, an illuminance sensor, and a camera sensor or an image sensor.

The color filter layer CFL may be disposed on the thin film encapsulation layer TFEL. The color filter layer CFL may include multiple color filters corresponding to each of the light emitting areas. Each of the color filters may selectively transmit light of a specific wavelength and block or absorb light of a different wavelength. The color filter layer CFL may absorb a portion of light introduced from the outside of the display device 10 to reduce reflected light caused by external light. Therefore, the color filter layer CFL may prevent color distortion caused by reflection of external light.

As the color filter layer CFL is directly disposed on the thin film encapsulation layer TFEL, the display device 10 may not require a separate substrate for the color filter layer CFL. Therefore, the display device 10 may have a relatively small thickness.

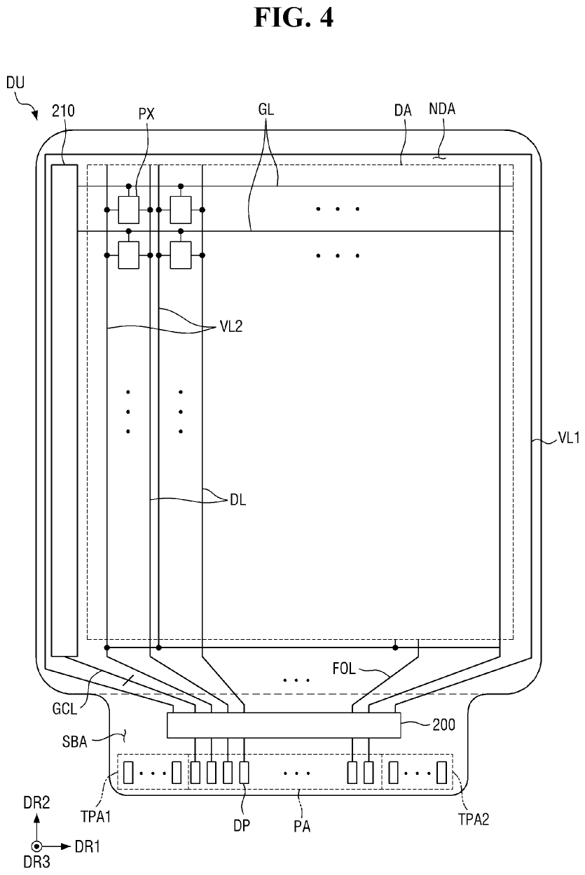

FIG. 4 is a schematic plan view illustrating a display layer of the display device according to an embodiment.

Referring to FIG. 4, the display layer DU may include a display area DA and a non-display area NDA.

The display area DA may be disposed at a center of the display panel 100. Pixels PX, gate lines GL, data lines DL, and a portion (e.g., a second power line VL2) of power lines may be disposed in the display area DA. Each of the pixels PX may be defined as a minimum unit emitting light.

The gate lines GL may supply a gate signal received from a gate driver 210 to the pixels PX. The gate lines GL may extend in the first direction DR1 and may be spaced apart from each other in the second direction DR2 intersecting the first direction DR1.

The data lines DL may supply the data voltage received from the display driver 200 to the pixels PX. The data lines DL may extend in the second direction DR2 and may be spaced apart from each other in the first direction DR1.

The second power line VL2 of the power lines may supply the power voltage received from the display driver 200 to the pixels PX. Here, the power voltage may be at least one of a driving voltage, an initialization voltage, and a reference voltage. The second power lines VL2 may extend in the second direction DR2 and may be spaced apart from each other in the first direction DR1.

The non-display area NDA may surround the display area DA. A portion (e.g., a first power line VL1) of the power lines, a gate driver 210, fan-out lines FOL, and gate control lines GCL may be disposed in the non-display area NDA. The gate driver 210 may generate gate signals based on the gate control signal, and may sequentially supply the gate signals to the gate lines GL according to a set order.

The fan-out lines FOL may extend from the display driver 200 to the display area DA. The fan-out lines FOL may supply the data voltages received from the display driver 200 to the data lines DL.

The gate control line GCL may extend from the display driver 200 to the gate driver 210. The gate control line GCL may supply the gate control signal received from the display driver 200 to the gate driver 210. It is illustrated in the drawing that the gate driver 210 is disposed only in the non-display area NDA disposed on the left side of the display area DA, but the disclosure is not limited thereto. In some embodiments, the display device 10 may also include multiple gate drivers 210 respectively disposed on, e.g., the left and right sides of the display area DA.

The first power line VL1 of the power lines may surround the display area DA and may be disposed in the non-display area NDA. The first power line VL1 may supply the power voltage received from the display driver 200 to the pixels PX. Here, the power voltage may be a low-potential power voltage.

The sub-area SBA may include a display driver 200, a pad area PA, and first and second touch pad areas TPA1 and TPA2.

The display driver 200 may output signals and voltages for driving the display panel 100 to the fan-out lines FOL. The display driver 200 may supply the data voltage to the data lines DL through the fan-out lines FOL. The data voltage may be supplied to the pixels PX and may control luminance of the pixels PX. The display driver 200 may supply the gate control signal to the gate driver 210 through the gate control line GCL.

The pad area PA, the first touch pad area TPA1, and the second touch pad area TPA2 may be disposed at an edge of the sub-area SBA. The pad area PA, the first touch pad area TPA1, and the second touch pad area TPA2 may be electrically connected to the circuit board 300 using an anisotropic conductive film or a material such as a self assembly anisotropic conductive paste SAP.

The pad area PA may include display pad portions DP. The display pad portions DP may be connected to a graphic system through the circuit board 300. The display pad portions DP may be connected to the circuit board 300 to receive digital video data, and may supply the digital video data to the display driver 200.

FIG. 5 is a schematic plan view illustrating an arrangement of light emitting areas and color filters in a display area of the display device according to an embodiment.

Referring to FIG. 5, the display device 10 may include light emitting areas EA1, EA2, and EA3 disposed in the display area DA. The display area DA illustrated in FIG. 5 is the first display area DA1, and the light emitting areas EA1, EA2, and EA3 may be disposed in the first display area DAL. However, the light emitting areas EA1, EA2, and EA3 may also be disposed in the second display area DA2 and the third display area DA3 of the display area DA.

The light emitting areas EA1, EA2, and EA3 may include a first light emitting area EA1, a second light emitting area EA2, and a third light emitting area EA3 that emit light of different colors. The first to third light emitting areas EA1, EA2, and EA3 may emit red, green, or blue light, respectively, and the color of light emitted from each of the light emitting areas EA1, EA2, and EA3 may be different depending on the types of light emitting elements (‘ED1’, ‘ED2’, and ‘ED3’ in FIG. 6) disposed in the light emitting element layer EML to be described later. In an embodiment, the first light emitting area EA1 may emit first light in red, the second light emitting area EA2 may emit second light in green, and the third light emitting area EA3 may emit third light in blue. However, the disclosure is not limited thereto.

The light emitting areas EA1, EA2, and EA3 may be disposed in a Pentile™ type, for example, a diamond Pentile™ type. For example, the first light emitting area EA1 and the third light emitting area EA3 may be disposed to be spaced apart from each other in the first direction DR1, and may be alternately disposed in the first direction DR1 and the second direction DR2. In the arrangement of the light emitting areas EA1, EA2, and EA3, the first light emitting area EA1 and the third light emitting area EA3 may be alternately disposed in the first direction DR1 in a first row R1 and a third row R3. The first light emitting area EA1 and the third light emitting area EA3 may be alternately disposed in the second direction DR2 in a first column C1 and a third column C3.

The second light emitting area EA2 may be spaced apart from another adjacent second light emitting area EA2 in the first and second directions DR1 and DR2, and may be spaced apart from the adjacent first light emitting area EA1 and third light emitting area EA3 in a fourth direction DR4 or a fifth direction DR5. The second light emitting areas EA2 may be repeatedly disposed along the first and second directions DR1 and DR2, and the second light emitting area EA2 and the first light emitting area EA1, or the second light emitting area EA2 and the third light emitting area EA3 may be alternately disposed along the fourth direction DR4 or the fifth direction DR5. In the arrangement of the light emitting areas EA1, EA2, and EA3, the second light emitting area EA2 may be repeatedly disposed in the first direction DR1 in a second row R2 and a fourth row R4, and the second light emitting area EA2 may be repeatedly disposed in the second direction DR2 in a second column C2 and a fourth column C4.

Each of the first to third light emitting areas EA1, EA2, and EA3 may be defined by openings OPE1, OPE2, and OPE3 formed in a bank structure (‘BNS’ in FIG. 6) of the light emitting element layer EML, which will be described later. For example, the first light emitting area EA1 may be defined by the first opening OPE1 of the pixel defining film, the second light emitting area EA2 may be defined by the second opening OPE2 of the pixel defining film, and the third light emitting area EA3 may be defined by the third opening OPE3 of the pixel defining film.

Areas of the light emitting areas EA1, EA2, and EA3 may vary according to sizes of the openings OPE1, OPE2, and OPE3 of the bank structure. Intensities of light emitted from the light emitting areas EA1, EA2, and EA3 may vary depending on the areas of the light emitting areas EA1, EA2, and EA3, and a color of a screen displayed on the display device 10 or the electronic device 1 may be controlled by adjusting the areas of the light emitting areas EA1, EA2, and EA3. In an embodiment, the areas or sizes of the first to third light emitting areas EA1, EA2, and EA3 may be the same. In the embodiment of FIG. 6, the first light emitting area EA1, the second light emitting area EA2, and the third light emitting area EA3 may have the same area or diameter.

However, the disclosure is not limited thereto. The areas of the light emitting areas EA1, EA2, and EA3 may be freely adjusted according to the color of the screen required by the display device 10 and the electronic device 1. The areas of the light emitting areas EA1, EA2, and EA3 may be related to light efficiency and lifespan of the light emitting elements ED1, ED2, and ED3, and may have a trade-off relationship with reflection by external light. The areas of the light emitting areas EA1, EA2, and EA3 may be adjusted in consideration of the above-mentioned matters. For example, in the display device 10, the area of the third light emitting area EA3 may be greater than the areas of the first light emitting area EA1 and the second light emitting area EA2, and the area of the first light emitting area EA1 may be greater than the area of the second light emitting area EA2.

In the display device 10 having the arrangement of the light emitting areas EA1, EA2, and EA3 as illustrated in FIG. 5, one first light emitting area EA1, two second light emitting areas EA2, and one third light emitting area EA3 disposed adjacent to each other may form one pixel group. One pixel group may express a white gradation by including the light emitting areas EA1, EA2, and EA3 emitting light of different colors. However, the disclosure is not limited thereto, and a combination of the light emitting areas EA1, EA2, and EA3 constituting one pixel group may be variously modified according to the arrangement of the light emitting areas EA1, EA2, and EA3, and the colors of the light emitted therefrom.

The display device 10 may include color filters CF1, CF2, and CF3 disposed on the light emitting areas EA1, EA2, and EA3. Each of the color filters CF1, CF2, and CF3 may be disposed to correspond to the light emitting areas EA1, EA2, and EA3. For example, the color filters CF1, CF2, and CF3 may be disposed in opening holes OPT1, OPT2, and OPT3 of a light blocking layer BM disposed to correspond to the light emitting areas EA1, EA2, and EA3 or the openings OPE1, OPE2, and OPE3. The opening holes OPT1, OPT2, and OPT3 of the light blocking layer may be formed to overlap the openings OPE1, OPE2, and OPE3, and may form light outputting areas in which light emitted from the light emitting areas EA1, EA2, and EA3 is emitted. Each of the color filters CF1, CF2, and CF3 may have a larger area than the openings OPE1, OPE2, and OPE3, and may completely cover the light outputting areas formed by the opening holes OPT1, OPT2, and OPT3 of the light blocking layer BM.

The color filters CF1, CF2, and CF3 may include a first color filter CF1, a second color filter CF2, and a third color filter CF3 disposed to correspond to different light emitting areas EA1, EA2, and EA3, respectively. The color filters CF1, CF2, and CF3 may include a colorant such as a dye or pigment that absorbs light in a wavelength band other than light in a specific wavelength band, and may be disposed to correspond to the colors of light emitted from the light emitting areas EA1, EA2, and EA3. For example, the first color filter CF1 may be a red color filter that is disposed to overlap the first light emitting area EA1 and may transmit only first light in red. The second color filter CF2 may be a green color filter that is disposed to overlap the second light emitting area EA2 and may transmit only second light in green, and the third color filter CF3 may be a blue color filter that is disposed to overlap the third light emitting area EA3 and may transmit only third light in blue.

Similar to the arrangement of the light emitting areas EA1, EA2, and EA3, the color filters CF1, CF2, and CF3 may be disposed in a Pentile™ type, for example, a diamond Pentile™ type. For example, the first color filter CF1 and the third color filter CF3 may be alternately disposed in the first direction DR1 and the second direction DR2. In the arrangement of the color filters CF1, CF2, and CF3, the first color filter CF1 and the third color filter CF3 may be alternately disposed in the first direction DR1 in a first row R1 and a third row R3. The first color filter CF1 and the third color filter CF3 may be alternately disposed in the second direction DR2 in a first column C1 and a third column C3.

The second color filter CF2 may be arranged with another adjacent second color filter CF2 in the first direction DR1 and in the second direction DR2, and may be disposed with adjacent first and third color filters CF1 and CF3 in the fourth direction DR4 or the fifth direction DR5. The second color filters CF2 may be repeatedly disposed along the first and second directions DR1 and DR2, and the second color filter CF2 and the first color filter CF1, or the second color filter CF2 and the third color filter CF3 may be alternately disposed along the fourth direction DR4 or the fifth direction DR5. In the arrangement of the color filters CF1, CF2, and CF3, the second color filter CF2 may be repeatedly disposed in the first direction DR1 in a second row R2 and a fourth row R4, and the second color filter CF2 may be repeatedly disposed in the second direction DR2 in a second column C2 and a fourth column C4.

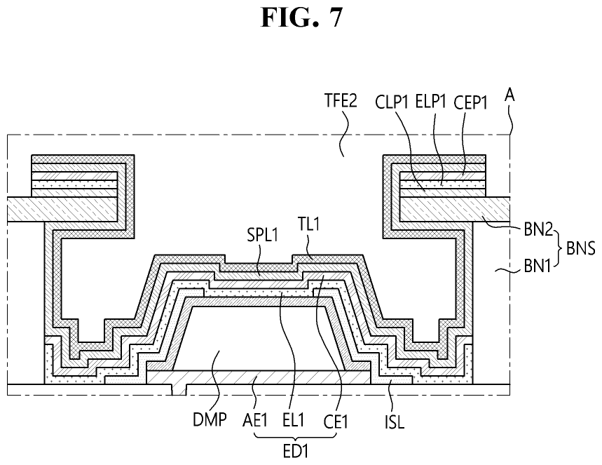

FIG. 6 is a schematic cross-sectional view illustrating a portion of the display device according to an embodiment. FIG. 7 is an enlarged schematic view illustrating a first light emitting area of FIG. 6. FIG. 6 is a partial cross-sectional view of the display device 10 and illustrates cross-sections of the substrate SUB, the thin film transistor layer TFTL, the light emitting element layer EML, the thin film encapsulation layer TFEL, the touch sensing layer TSU, and the color filter layer CFL of the display layer DU. FIG. 7 illustrates a portion of the first light emitting element ED1 disposed in the first light emitting area EA1 and the bank structure BNS around the first light emitting element ED1 as part A of FIG. 6.

Referring to FIGS. 6 and 7 together with FIG. 5, the display panel 100 of the display device 10 may include the display layer DU. The display layer DU may include a substrate SUB, a thin film transistor layer TFTL, a light emitting element layer EML, and a thin film encapsulation layer TFEL. The display panel 100 may include a light blocking layer BM disposed on the thin film encapsulation layer TFEL, and the color filters CF1, CF2, and CF3 of the color filter layer CFL may be disposed on the light blocking layer BM.

The substrate SUB may be a base substrate or a base member. The substrate SUB may be a flexible substrate that may be bent, folded, rolled, or the like. For example, the substrate SUB may include a polymer resin such as polyimide (PI), but is not limited thereto. As another example, the substrate SUB may include a glass material and/or a metal material.

The thin film transistor layer TFTL may include a first buffer layer BF1, a lower metal layer BML, a second buffer layer BF2, a thin film transistor TFT, a gate insulating layer GI, a first interlayer insulating layer ILD1, a capacitor electrode CPE, a second interlayer insulating layer ILD2, a first connection electrode CNE1, a first passivation layer PAS1, a second connection electrode CNE2, and a second passivation layer PAS2.

The first buffer layer BF1 may be disposed on the substrate SUB. The first buffer layer BF1 may include an inorganic film capable of preventing permeation of air or moisture. For example, the first buffer layer BF1 may include multiple inorganic films stacked on each other.

The lower metal layer BML may be disposed on the first buffer layer BF1. For example, the lower metal layer BML may be formed as a single layer or multiple layers made of at least one of molybdenum (Mo), aluminum (Al), chromium (Cr), gold (Au), titanium (Ti), nickel (Ni), neodymium (Nd), and copper (Cu), or an alloy thereof.

The second buffer layer BF2 may cover the first buffer layer BF1 and the lower metal layer BML. The second buffer layer BF2 may include an inorganic film capable of preventing permeation of air or moisture. For example, the second buffer layer BF2 may include multiple inorganic films stacked on each other.

The first thin film transistor TFT may be disposed on the second buffer layer BF2 and may constitute a pixel circuit of each of the pixels. For example, the first thin film transistor TFT may be a driving transistor or a switching transistor of a pixel circuit disposed in the display area DA. The first thin film transistor TFT may include a semiconductor layer ACT, a source electrode SE, a drain electrode DE, and a gate electrode GE.

The semiconductor layer ACT may be disposed on the second buffer layer BF2. The semiconductor layer ACT may overlap the lower metal layer BML and the gate electrode GE in the thickness direction, and may be insulated from the gate electrode GE by the gate insulating layer GI. In a portion of the semiconductor layer ACT, a material of the semiconductor layer ACT may become a conductor to form the source electrode SE and the drain electrode DE.

The gate electrode GE may be disposed on the gate insulating layer GI. The gate electrode GE may overlap the semiconductor layer ACT with the gate insulating layer GI interposed therebetween.

The gate insulating layer GI may be disposed on the semiconductor layer ACT. For example, the gate insulating layer GI may cover the semiconductor layer ACT and the second buffer layer BF2, and may insulate the semiconductor layer ACT and the gate electrode GE from each other. The gate insulating layer GI may include a contact hole through which the first connection electrode CNE1 penetrates.

The first interlayer insulating layer ILD1 may cover the gate electrode GE and the gate insulating layer GI. The first interlayer insulating layer ILD1 may include a contact hole through which the first connection electrode CNE1 penetrates. The contact hole of the first interlayer insulating layer ILD1 may be connected to the contact hole of the gate insulating layer GI and a contact hole of the second interlayer insulating layer ILD2.

The capacitor electrode CPE may be disposed on the first interlayer insulating layer ILD1. The capacitor electrode CPE may overlap the gate electrode GE in the thickness direction. The capacitor electrode CPE and the gate electrode GE may form a capacitance.

The second interlayer insulating layer ILD2 may cover the capacitor electrode CPE and the first interlayer insulating layer ILD1. The second interlayer insulating layer ILD2 may include a contact hole through which the first connection electrode CNE1 penetrates. The contact hole of the second interlayer insulating layer ILD2 may be connected to the contact hole of the first interlayer insulating layer ILD1 and the contact hole of the gate insulating layer GI.

The first connection electrode CNE1 may be disposed on the second interlayer insulating layer ILD2. The first connection electrode CNE1 may electrically connect the drain electrode DE of the first thin film transistor TFT and the second connection electrode CNE2 to each other. The first connection electrode CNE1 may be inserted into the contact holes formed in the second interlayer insulating layer ILD2, the first interlayer insulating layer ILD1, and the gate insulating layer GI and be in contact with the drain electrode DE of the first thin film transistor TFT.

The first passivation layer PAS1 may cover the first connection electrode CNE1 and the second interlayer insulating layer ILD2. The first passivation layer PAS1 may protect the first thin film transistor TFT. The first passivation layer PAS1 may include a contact hole through which the second connection electrode CNE2 penetrates.

The second connection electrode CNE2 may be disposed on the first passivation layer PAS1. The second connection electrode CNE2 may electrically connect the first connection electrode CNE1 and anode electrodes AE1, AE2, and AE3 of a light emitting element ED1, ED2, or ED3 to each other. The second connection electrode CNE2 may be inserted into the contact hole formed in the first passivation layer PAS1 and be in contact with the first connection electrode CNE1.

The second passivation layer PAS2 may cover the second connection electrode CNE2 and the first passivation layer PAS1. The second passivation layer PAS2 may include contact holes through which the anode electrodes AE1, AE2, and AE3 of the light emitting element ED1, ED2 or ED3 penetrate.

The light emitting element layer EML may be disposed on the thin film transistor layer TFTL. The light emitting element layer EML may include a light emitting element (ED1, ED2, or ED3), bank structures BNS, capping layers CPL1, CPL2, and CPL3, and auxiliary common electrodes SPL1, SPL2, and SPL3. The light emitting elements ED1, ED2, and ED3 may include anode electrodes AE1, AE2, and AE3, light emitting layers EL1, EL2, and EL3, and cathode electrodes CE1, CE2, and CE3.

The display device 10 may include light emitting areas EA1, EA2, and EA3 disposed in the display area DA. The light emitting areas EA1, EA2, and EA3 may include a first light emitting area EA1, a second light emitting area EA2, and a third light emitting area EA3 that emit light of different colors. The first to third light emitting areas EA1, EA2, and EA3 may emit red, green, or blue light, respectively, and the color of light emitted from each of the light emitting areas EA1, EA2, and EA3 may be different depending on the types of light emitting elements disposed in the light emitting element layer EML. In an embodiment, the first light emitting area EA1 may emit first light in red, the second light emitting area EA2 may emit second light in green, and the third light emitting area EA3 may emit third light in blue. However, the disclosure is not limited thereto.

Each of the first to third light emitting areas EA1, EA2, and EA3 may be defined by the openings OPE1, OPE2, and OPE3 formed in the bank structure BNS of the light emitting element layer EML. For example, the first light emitting area EA1 may be defined by the first opening OPE1 of the bank structure BNS, the second light emitting area EA2 may be defined by the second opening OPE2 of the bank structure BNS, and the third light emitting area EA3 may be defined by the third opening OPE3 of the bank structure BNS.

In an embodiment, the areas or sizes of the first to third light emitting areas EA1, EA2, and EA3 may be the same. For example, in the display device 10, the openings OPE1, OPE2, and OPE3 of the bank structures BNS may have the same diameter, and the first light emitting area EA1, the second light emitting area EA2, and the third light emitting area EA3 may have the same area. However, the disclosure is not limited thereto. In the display device 10, the areas or sizes of the first to third light emitting areas EA1, EA2, and EA3 may be different from each other. For example, the area of the second light emitting area EA2 may be greater than the areas of the first light emitting area EA1 and the third light emitting area EA3, and the area of the third light emitting area EA3 may be greater than the area of the first light emitting area EA1. Intensities of light emitted from the light emitting areas EA1, EA2, and EA3 may vary depending on the areas of the light emitting areas EA1, EA2, and EA3, and a color of a screen displayed on the display device 10 or the electronic device 1 may be controlled by adjusting the areas of the light emitting areas EA1, EA2, and EA3. The areas of the light emitting areas EA1, EA2, and EA3 are illustrated to be the same in the embodiment of FIG. 5, but are not limited thereto. The areas of the light emitting areas EA1, EA2, and EA3 may be freely adjusted according to the color of the screen required by the display device 10 and the electronic device 1. The areas of the light emitting areas EA1, EA2, and EA3 may be related to light efficiency and lifespan of the light emitting elements ED1, ED2, and ED3, and may have a trade-off relationship with reflection by external light. The areas of the light emitting areas EA1, EA2, and EA3 may be adjusted in consideration of the above-mentioned matters.

In the display device 10, one first light emitting area EA1, one second light emitting area EA2, and one third light emitting area EA3 disposed adjacent to each other may form one pixel group. One pixel group may express a white gradation by including the light emitting areas EA1, EA2, and EA3 emitting light of different colors. However, the disclosure is not limited thereto, and a combination of the light emitting areas EA1, EA2, and EA3 constituting one pixel group may be variously modified according to the arrangement of the light emitting areas EA1, EA2, and EA3, and the colors of the light emitted therefrom.

The display device 10 may include light emitting elements ED1, ED2, and ED3 disposed in different light emitting areas EA1, EA2, and EA3. The light emitting elements ED1, ED2, and ED3 may include a first light emitting element ED1 disposed in the first light emitting area EA1, a second light emitting element ED2 disposed in the second light emitting area EA2, and a third light emitting element ED3 disposed in the third light emitting area EA3. Each of the light emitting elements ED1, ED2, and ED3 may include anode electrodes AE1, AE2, and AE3, light-emitting layers EL1, EL2, and EL3, and cathode electrodes CE1, CE2, and CE3, and the light emitting elements ED1, ED2, and ED3 disposed in different light emitting areas EA1, EA2, and EA3 may emit light of different colors depending on the material of the light emitting layers EL1, EL2, and EL3. For example, the first light emitting element ED1 disposed in the first light emitting area EA1 may emit red light of a first color, the second light emitting element ED2 disposed in the second light emitting area EA2 may emit green light of a second color, and the third light emitting element ED3 disposed in the third light emitting area EA3 may emit blue light of a third color. The first to third light emitting areas EA1, EA2, and EA3 constituting one pixel may express a white gradation by including the light emitting elements ED1, ED2, and ED3 that emit light of different colors.

The anode electrodes AE1, AE2, and AE3 may be disposed on the second passivation layer PAS2. The anode electrodes AE1, AE2, and AE3 may be disposed to overlap at least one of the openings OPE1, OPE2, and OPE3 of the bank structure BNS. The anode electrodes AE1, AE2, and AE3 may be electrically connected to the drain electrode DE of the first thin film transistor TFT through the first and second connection electrodes CNE1 and CNE2.

The anode electrodes AE1, AE2, and AE3 may be respectively disposed in the light emitting areas EA1, EA2, and EA3. The anode electrodes AE1, AE2, and AE3 may include a first anode electrode AE1 disposed in the first light emitting area EA1, a second anode electrode AE2 disposed in the second light emitting area EA2, and a third anode electrode AE3 disposed in the third light emitting area EA3. The first anode electrode AE1, the second anode electrode AE2, and the third anode electrode AE3 may be disposed to be spaced apart from each other on the second passivation layer PAS2. Each of the anode electrodes AE1, AE2, and AE3 may be disposed in different light emitting areas EA1, EA2, and EA3 to form the light emitting elements ED1, ED2, and ED3 that emit light of different colors. The anode electrodes AE1, AE2, and AE3 may include a metal material having high reflectivity. In an embodiment, the anode electrodes AE1, AE2, and AE3 may include a metal such as silver (Ag), magnesium (Mg), aluminum (Al), platinum (Pt), palladium (Pd), gold (Au), nickel (Ni), neodymium (Nd), iridium (Ir), and/or chromium (Cr). The anode electrodes AE1, AE2, and AE3 may include the above-mentioned materials and serve as reflective electrodes.

The display device 10 according to an embodiment may include dummy patterns DMP disposed on the anode electrodes AE1, AE2, and AE3 and capping layers CPL1, CPL2, and CPL3 disposed on the dummy patterns DMP.

The dummy pattern DMP may be directly disposed on the anode electrodes AE1, AE2, and AE3. The dummy pattern DMP may be disposed on the first to third anode electrodes AE1, AE2, and AE3, respectively. The display device 10 may include multiple dummy patterns DMP disposed on an entire surface of the display area DA to correspond to the light emitting areas EA1, EA2, and EA3. In the same manner as the arrangement of the light emitting areas EA1, EA2, and EA3, the dummy patterns DMP may be disposed to be spaced apart from each other in the first and second directions DR1 and DR2 or in the fourth and fifth directions DR4 and DR5 in the display area DA.

The dummy pattern DMP may have a smaller area than the anode electrodes AE1, AE2, and AE3 in plan view. Even if the dummy pattern DMP is disposed on the anode electrodes AE1, AE2, and AE3, some of the anode electrodes AE1, AE2, and AE3 may not overlap the dummy pattern DMP. A portion of the anode electrodes AE1, AE2, and AE3 that does not overlap the dummy pattern DMP may be in contact with the capping layers CPL1, CPL2, and CPL3. The dummy pattern DMP may include a transparent insulating material and have a greater thickness than the anode electrodes AE1, AE2, and AE3. The dummy pattern DMP may not be electrically connected to the anode electrodes AE1, AE2, and AE3, but the capping layers CPL1, CPL2, and CPL3 disposed on the anode electrodes AE1, AE2, and AE3 may be electrically connected to the anode electrodes AE1, AE2, and AE3 to form an equipotential. The display device 10 may include the dummy pattern DMP to form an equipotential surface at a position higher than a position where the anode electrodes AE1, AE2, and AE3 are disposed. In an embodiment, the dummy pattern DMP may include silicon oxide (SiOₓ), silicon nitride (SiNₓ), and/or silicon oxynitride (SiOₓN_{y}), in an embodiment silicon oxide (SiOₓ).

The capping layers CPL1, CPL2, and CPL3 may be disposed to cover the dummy pattern DMP and may be electrically connected to the anode electrodes AE1, AE2, and AE3. The capping layers CPL1, CPL2, and CPL3 may be disposed on the anode electrodes AE1, AE2, and AE3 with the dummy pattern DMP interposed therebetween. A portion of the dummy pattern DMP may be spaced apart from the anode electrodes AE1, AE2, and AE3, and a portion thereof may be in direct contact with the anode electrodes AE1, AE2, and AE3.

A first capping layer CPL1 may be disposed on the first anode electrode AE1 and may be partially in contact with the first anode electrode AE1. A second capping layer CPL2 may be disposed on the second anode electrode AE2 and may be partially in contact with the second anode electrode AE2, and a third capping layer CPL3 may be disposed on the third anode electrode AE3 and may be partially in contact with the third anode electrode AE3. The capping layers CPL1, CPL2, and CPL3 may include a transparent material having high electrical conductivity and may be electrically connected to the anode electrodes AE1, AE2, and AE3. The capping layers CPL1, CPL2, and CPL3 may form an equipotential with the anode electrodes AE1, AE2, and AE3 and may serve as one electrode of the light emitting elements ED1, ED2, and ED3. In an embodiment, the capping layers CPL1, CPL2, and CPL3 may include at least one of indium tin oxide (ITO), indium gallium zinc oxide (IGZO), zinc tin oxide (ZTO), indium tin oxide (IZO).

The light emitting elements ED1, ED2, and ED3 of the display device 10 may emit light generated by light emitting layers EL1, EL2, and EL3 to be described later. A portion of the light generated by the light emitting layers EL1, EL2, and EL3 may travel in an upper direction and be emitted to the cathode electrodes CE1, CE2, and CE3, and another portion of the light generated by the light emitting layers EL1, EL2, and EL3 may travel in a lower direction and be reflected by the anode electrodes AE1, AE2, and AE3. The light emitting elements ED1, ED2, and ED3 may have an optical thickness designed so that light reflected from the anode electrodes AE1, AE2, and AE3 may cause constructive interference with other lights through a thickness between the anode electrodes AE1, AE2, and AE3 and the cathode electrodes CE1, CE2, and CE3.

The thickness between the anode electrodes AE1, AE2, and AE3 and the cathode electrodes CE1, CE2, and CE3 may be designed by increasing a thickness of the light emitting layers EL1, EL2, and EL3, and a driving voltage of the light emitting elements ED1, ED2, and ED3 may increase, and thus driving characteristics may be deteriorated. In other embodiments, the optical thickness of the light emitting elements ED1, ED2, and ED3 may be designed through a thickness of the capping layers CPL1, CPL2, and CPL3 disposed on the anode electrodes AE1, AE2, and AE3. However, in the case in which the capping layers CPL1, CPL2, and CPL3 include ITO, as the thickness of the capping layers increases, etching characteristics may be deteriorated and light absorbing characteristics may occur, so that light output efficiency of the light emitting elements ED1, ED2, and ED3 may decrease.

The display device 10 according to an embodiment may include the dummy pattern DMP disposed between the anode electrodes AE1, AE2, and AE3 and the capping layers CPL1, CPL2, and CPL3 of the light emitting elements ED1, ED2, and ED3, and have an appropriate driving voltage while having an optical thickness required for the light emitting elements ED1, ED2, and ED3. As the dummy pattern DMP includes the transparent material, the display device 10 may have a sufficient thickness between the cathode electrodes CE1, CE2, and CE3 and the anode electrodes AE1, AE2, and AE3. In the display device 10 according to an embodiment, a gap between the cathode electrodes CE1, CE2, and CE3 and the anode electrodes AE1, AE2, and AE3 of the light emitting elements ED1, ED2, and ED3 may be greater than the thickness of the light emitting layers EL1, EL2, and EL3. Since the capping layers CPL1, CPL2, and CPL3 forming the equipotential with the anode electrodes AE1, AE2, and AE3 are disposed on the dummy pattern DMP, the light emitting layers EL1, EL2, and EL3 may have a thin thickness and thus driving voltage characteristics may also be excellent.

The inorganic insulating layer ISL may be disposed on the dummy pattern DMP, the capping layers CPL1, CPL2, and CPL3, and the anode electrodes AE1, AE2, and AE3. The inorganic insulating layer ISL may be disposed to cover the anode electrodes AE1, AE2, and AE3 and the capping layers CPL1, CPL2, and CPL3, and may expose portions of upper surfaces of the capping layers CPL1, CPL2, and CPL3. The inorganic insulating layer ISL may expose the capping layers CPL1, CPL2, and CPL3 at portions overlapping the openings OPE1, OPE2, and OPE3 of the bank structure BNS, and the light emitting layers EL1, EL2, and EL3 disposed on the capping layers CPL1, CPL2, and CPL3 may be directly disposed on the capping layers CPL1, CPL2, and CPL3. The inorganic insulating layer ISL may be disposed to expose the capping layers CPL1, CPL2, and CPL3 and completely cover the anode electrodes AE1, AE2, and AE3. For example, the inorganic insulating layer ISL may completely cover side surfaces of the anode electrodes AE1, AE2, and AE3. However, the inorganic insulating layer ISL may be spaced apart from the bank structure BNS. As illustrated in the drawing, the inorganic insulating layer ISL may be completely spaced apart from and not in contact with the bank structure BNS, but is not limited thereto. In some embodiments, the inorganic insulating layer ISL may not cover at least a second bank layer BN2 of the bank structure BNS to be described later. The inorganic insulating layer ISL may include an inorganic insulating material. In an example, the inorganic insulating layer ISL may include aluminum oxide, titanium oxide, tantalum oxide, hafnium oxide, zinc oxide, silicon oxide, silicon nitride, and/or silicon oxynitride.

The display device 10 may include bank structures BNS disposed on the thin film transistor layer TFTL or the substrate SUB and including openings OPE1, OPE2, and OPE3. The bank structures BNS may have a structure in which bank layers BN1 and BN2 including different materials are stacked on each other and may include the openings OPE1, OPE2, and OPE3 forming the light emitting areas EA1, EA2, and EA3. The light emitting elements ED1, ED2, and ED3 of the display device 10 may be disposed to overlap the openings OPE1, OPE2, and OPE3 of the bank structure BNS. The bank structure BNS may be disposed to surround the anode electrodes AE1, AE2, and AE3, respectively.

The bank structure BNS may include a first bank layer BN1 disposed on the second passivation layer PAS2 and a second bank layer BN2 disposed on the first bank layer BN1.

According to an embodiment, the first bank layer BN1 and the second bank layer BN2 may include different materials, and the bank structure BNS may include a tip of the second bank layer BN2 protruding from the first bank layer BN1 toward the openings OPE1, OPE2, and OPE3. In the bank structure BNS, sides of the first bank layer BN1 may have a shape depressed inward from a side of the second bank layer BN2. In the bank structure BNS, the first bank layer BN1 may have a thicker thickness than the second bank layer BN2, and since the second bank layer BN2 has a relatively thin thickness, the tip may be formed in a fabricating process. As the second bank layer BN2 protrudes toward the openings OPE1, OPE2, and OPE3 more than the first bank layer BN1, inner sidewalls of the openings OPE1, OPE2, and OPE3 of the bank structure BNS may have an undercut formed on a lower portion of the tip of the second bank layer BN2.

The shape of the sidewall of the bank structure BNS may be a structure formed due to a difference in etching rate in an etching process because the first bank layer BN1 and the second bank layer BN2 include different materials. According to an embodiment, the second bank layer BN2 may include a material having a slower etching rate than the first bank layer BN1, and in the process of forming the openings OPE1, OPE2, and OPE3 of the bank structure BNS, the first bank layer BN1 may be further etched to form the undercut on a lower portion of the tip of the second bank layer BN2. In an embodiment, the first bank layer BN1 includes an insulating material including the same material as the dummy pattern DMP, and the second bank layer BN2 may include a metal material having low reflectivity. As an example, the first bank layer BN1 may include silicon oxide (SiOₓ), silicon nitride (SiNₓ), or silicon oxynitride (SiOₓN_{y}), and the second bank layer BN2 may include titanium (Ti). For example, the bank structure BNS may have a structure in which SiOₓ/Ti is stacked, and the tip may be formed in a Ti layer of the second bank layer BN2.

In the display device 10 according to an embodiment, the first bank layer BN1 may include the same material as the dummy pattern DMP. Since the first bank layer BN1 is formed together in the process of forming the dummy pattern DMP, there may be an advantage in that a separate process is not required in the fabricating process. However, since the second bank layer BN2 is formed on the first bank layer BN1 in the process of fabricating the display device 10, the first bank layer BN1 may have a different thickness from that of the dummy pattern DMP due to a different etching rate. The first bank layer BN1 may have a thickness greater than that of the dummy pattern DMP, and may form the openings OPE1, OPE2, and OPE3 in which the light emitting elements ED1, ED2, and ED3 are disposed.

The bank structure BNS may include the openings OPE1, OPE2, and OPE3 forming the light emitting areas EA1, EA2, and EA3, and the light blocking layer BM may be disposed thereon. An uppermost layer of the bank structure BNS may reduce reflection of external light by including a material having low reflectivity. In the bank structure BNS, the second bank layer BN2 may be electrically connected to the auxiliary common electrodes SPL1, SPL2, and SPL3 disposed on the cathode electrodes CE1, CE2, and CE3 of the different light emitting elements ED1, ED2, and ED3. The light emitting elements ED1, ED2, and ED3 disposed in different light emitting areas EA1, EA2, and EA3 may not be directly connected to the cathode electrodes CE1, CE2, and CE3, but may be electrically connected to the cathode electrodes CE1, CE2, and CE3 through the first bank layer BN1 of the bank structure BNS.

In order to form the pixel defining film forming the light emitting areas EA1, EA2, and EA3 with an organic material, or to form the light emitting layers EL1, EL2, and EL3 of the light emitting elements ED1, ED2, and ED3 for each of the light emitting areas EA1, EA2, and EA3 in the process of fabricating the display device 10, a mask process may be required. To perform the mask process, the display device 10 may require a structure for holding a mask, or may require an unnecessarily wide area of the non-display area NDA to control dispersion according to the mask process. If such a mask process is minimized, unnecessary components in the display device 10, for example, the structure for holding the mask may be omitted, and the area of the non-display area NDA for dispersion control may be minimized.

The display device 10 according to an embodiment includes the bank structure BNS forming the light emitting areas EA1, EA2, and EA3, and the bank structure BNS may be formed through a deposition and etching process rather than a mask process. As the bank structure BNS includes the first bank layer BN1 and the second bank layer BN2 including different metal materials and the inner sidewalls of the openings OPE1, OPE2, and OPE3 have a structure including the tip, it is also possible to individually form different layers in different light emitting areas EA1, EA2, and EA3 by the deposition process. For example, even if the light emitting layers EL1, EL2, and EL3 and the cathode electrodes CE1, CE2, and CE3 of the light emitting elements ED1, ED2, and ED3 are formed by the deposition process without using the mask, materials deposited by the tip of the second bank layer BN2 formed on the inner sidewalls of the openings OPE1, OPE2, and OPE3 may be disconnected and not connected between the openings OPE1, OPE2, and OPE3. It is possible to individually form different layers in different light emitting areas EA1, EA2, and EA3 through a process of forming a material for forming a specific layer on the entire surface of the display device 10 and etching and removing a layer formed in an unwanted area. In the display device 10, different light emitting elements ED1, ED2, and ED3 may be formed for each of the light emitting areas EA1, EA2, and EA3 through the deposition and etching processes without using the mask process, and an unnecessary configuration may be omitted from the display device 10 and the area of the non-display area NDA may be minimized.

The light emitting layers EL1, EL2, and EL3 may be disposed on the capping layers CPL1, CPL2, and CPL3 and the inorganic insulating layer ISL. The light emitting layers EL1, EL2, and EL3 may be organic light emitting layers made of organic materials, and may be formed on exposed portions of the capping layers CPL1, CPL2, and CPL3 where the inorganic insulating layer ISL is not disposed through the deposition process. The light emitting layers EL1, EL2, and EL3 may partially be in direct contact with the capping layers CPL1, CPL2, and CPL3.

In the light emitting layers EL1, EL2, and EL3, in case that the first thin film transistor TFT applies a predetermined or selected voltage to the anode electrodes AE1, AE2, and AE3 of the light emitting elements ED1, ED2, and ED3 and the cathode electrodes CE1, CE2, and CE3 of the light emitting elements ED1, ED2, and ED3 receive a common voltage or a cathode voltage, holes and electrons may respectively move to the light emitting layers EL1, EL2, and EL3 through the hole transport layer and the electron transport layer, and may be bonded with each other in the light emitting layers EL1, EL2, and EL3 to emit light.

According to an embodiment, the light emitting layers EL1, EL2, and EL3 may cover the inorganic insulating layer ISL and may also be disposed on the side surface of the first bank layer BN1 of the bank structure BNS within the light emitting areas EA1, EA2, and EA3. The deposition process of the light emitting layers EL1, EL2, and EL3 may be performed such that the material of the light emitting layer is deposited in an inclined direction rather than a direction perpendicular to the upper surface of the substrate SUB. Accordingly, the light emitting layers EL1, EL2, and EL3 may also be disposed on the capping layers CPL1, CPL2, and CPL3, the inorganic insulating layer ISL, and the side surface of the first bank layer BN1 of the bank structure BNS. As described above, the first bank layer BN1 may include an insulating material layer, and even if the first bank layer BN1 is in direct contact with the light emitting layers EL1, EL2, and EL3, a leakage current may not flow to other adjacent light emitting areas EA1, EA2, and EA3.

The light emitting layers EL1, EL2, and EL3 may include a first light emitting layer EL1, a second light emitting layer EL2, and a third light emitting layer EL3 disposed in different light emitting areas EA1, EA2, and EA3. The first light emitting layer EL1 may be disposed on the first capping layer CPL1 in the first light emitting area EA1, the second light emitting layer EL2 may be disposed on the second capping layer CPL2 in the second light emitting area EA2, and the third light emitting layer EL3 may be disposed on the third capping layer CPL3 in the third light emitting area EA3. The first to third light emitting layers EL1, EL2, and EL3 may be light emitting layers of the first to third light emitting elements ED1, ED2, and ED3, respectively. The first light emitting layer EL1 may be a light emitting layer that emits red light of a first color, the second light emitting layer EL2 may be a light emitting layer that emits green light of a second color, and the third light emitting layer EL3 may be a light emitting layer that emits blue light of a third color.

The cathode electrodes CE1, CE2, and CE3 may be disposed on the light emitting layers EL1, EL2, and EL3. The cathode electrodes CE1, CE2, and CE3 may include a transparent conductive material so that the light generated in the light emitting layers EL1, EL2, and EL3 may be emitted. The cathode electrodes CE1, CE2, and CE3 may receive a common voltage or a low potential voltage. In case that the anode electrodes AE1, AE2, and AE3 receive a voltage corresponding to the data voltage and the cathode electrodes CE1, CE2, and CE3 receive a low potential voltage, the light emitting layers EL1, EL2, and EL3 may emit light as a potential difference may be formed between the anode electrodes AE1, AE2, and AE3 and the cathode electrodes CE1, CE2, and CE3.

The cathode electrodes CE1, CE2, and CE3 may include a first cathode electrode CE1, a second cathode electrode CE2, and a third cathode electrode CE3 disposed in different light emitting areas EA1, EA2, and EA3. The first cathode electrode CE1 may be disposed on the first light emitting layer EL1 in the first light emitting area EA1, the second cathode electrode CE2 may be disposed on the second light emitting layer EL2 in the second light emitting area EA2, and the third cathode electrode CE3 may be disposed on the third light emitting layer EL3 in the third light emitting area EA3. In an embodiment, the cathode electrodes CE1, CE2, and CE3 may include a transparent conductive material. For example, the cathode electrodes CE1, CE2, and CE3 may include an AgMg alloy.

According to an embodiment, a portion of the cathode electrodes CE1, CE2, and CE3 of the light emitting elements ED1, ED2, and ED3 may be disposed on a side surface of the first bank layer BN1 of the bank structure BNS. Similar to the light emitting layers EL1, EL2, and EL3, the cathode electrodes CE1, CE2, and CE3 may also be formed through a deposition process. The deposition process of the cathode electrodes CE1, CE2, and CE3 may be performed such that an electrode material is deposited in an inclined direction rather than a direction perpendicular to the upper surface of the substrate SUB. Accordingly, the cathode electrodes CE1, CE2, and CE3 may be disposed on the side surface of the first bank layer BN1 on the lower portion of the tip of the second bank layer BN2 of the bank structure BNS. The cathode electrodes CE1, CE2, and CE3 may be in direct contact with the side surface of the first bank layer BN1. However, as described above, the first bank layer BN1 may include the insulating material layer, and even if the first bank layer BN1 is in direct contact with the cathode electrodes CE1, CE2, and CE3, a leakage current may not flow to other adjacent light emitting areas EA1, EA2, and EA3.

According to an embodiment, a contact area between the cathode electrodes CE1, CE2, and CE3 and the side surface of the first bank layer BN1 may be greater than a contact area between the light emitting layers EL1, EL2, EL3 and the side surface of the first bank layer BN1. The deposition processes of the cathode electrodes CE1, CE2, and CE3 and the light emitting layers EL1, EL2, and EL3 are performed such that the materials are deposited in an inclined direction rather than a direction perpendicular to the upper surface of the substrate SUB, and positions of the cathode electrodes CE1, CE2, and CE3 and the light emitting layers EL1, EL2, and EL3 disposed on the side surface of the first bank layer BN1 may vary according to the inclination angle. In an embodiment, the deposition process of the cathode electrodes CE1, CE2, and CE3 may be performed in a more inclined direction than the deposition process of the light emitting layers EL1, EL2, and EL3. The cathode electrodes CE1, CE2, and CE3 on the sidewalls of the openings OPE1, OPE2, and OPE3 may be disposed at higher positions on the sidewalls of the openings OPE1, OPE2, and OPE3 than the light emitting layers EL1, EL2, and EL3.

The auxiliary common electrodes SPL1, SPL2, and SPL3 may be disposed on the cathode electrodes CE1, CE2, and CE3 and the bank structure BNS. The auxiliary common electrodes SPL1, SPL2, and SPL3 may be disposed on the cathode electrodes CE1, CE2, and CE3 and the bank structure BNS. For example, the auxiliary common electrodes SPL1, SPL2, and SPL3 may include a first auxiliary common electrode SPL1 disposed on the first light emitting element ED1, a second auxiliary common electrode SPL2 disposed on the second light emitting element ED2, and a third auxiliary common electrode SPL3 disposed on the third light emitting element ED3. The first auxiliary common electrode SPL1 may be disposed on the first cathode electrode CE1, the second auxiliary common electrode SPL2 may be disposed on the second cathode electrode CE2, and the third auxiliary common electrode SPL3 may be disposed on the third cathode electrode CE3. The first to third auxiliary common electrodes SPL1, SPL2, and SPL3 may include a transparent conductive material and be electrically connected to the light emitting elements ED1, ED2, and ED3. In an embodiment, the auxiliary common electrodes SPL1, SPL2, and SPL3 may include a material such as ITO, IZO, and/or TiN.

According to an embodiment, the auxiliary common electrodes SPL1, SPL2, and SPL3 may be formed through a process such as chemical vapor deposition (CVD) or atomic layer deposition (ALD), unlike the light emitting layers EL1, EL2, and EL3 and the cathode electrodes CE1, CE2, and CE3. The auxiliary common electrodes SPL1, SPL2, and SPL3 may be formed along surface shapes of the bank structure BNS and the light emitting elements ED1, ED2, and ED3. The auxiliary common electrodes SPL1, SPL2, and SPL3 may be disposed on the cathode electrodes CE1, CE2, and CE3 of the light emitting elements ED1, ED2, and ED3, and may be formed to fill the side surface of the first bank layer BN1 and the lower portion of the tip of the second bank layer BN2 of the bank structure BNS. The auxiliary common electrodes SPL1, SPL2, and SPL3 may completely cover the side surface of the first bank layer BN1, and may cover the lower surface and side surface of the tip of the second bank layer BN2. In other embodiments, the auxiliary common electrodes SPL1, SPL2, and SPL3 may surround the tip of the second bank layer BN2. The light emitting layers EL1, EL2, and EL3 and the cathode electrodes CE1, CE2, and CE3 may be in contact with only a portion of the side surface of the first bank layer BN1 because of being formed through the process of depositing the materials. On the other hand, the auxiliary common electrodes SPL1, SPL2, and SPL3 may completely cover the side surface of the first bank layer BN1.

As the first bank layer BN1 includes the insulating material, a common electrode layer may not be formed with the light emitting elements ED1, ED2, and ED3 even if the cathode electrodes CE1, CE2, and CE3 may be in contact with the side surface of the first bank layer BN1. The auxiliary common electrodes SPL1, SPL2, and SPL3 may be in contact with the first bank layer BN1 and the second bank layer BN2, respectively, and the first to third auxiliary common electrodes SPL1, SPL2, and SPL3 disposed on the different light emitting elements ED1, ED2, and ED3 may be electrically connected to the second bank layer BN2, respectively. In the display device 10, the common electrode layer may be formed through the auxiliary common electrodes SPL1, SPL2, and SPL3 and the second bank layer BN2, while the light emitting layers EL1, EL2, and EL3 and the cathode electrodes CE1, CE2, and CE3 of the light emitting elements ED1, ED2, and ED3 may be in contact with only the first bank layer BN1 to prevent the leakage current between different light emitting elements ED1, ED2, and ED3.

The display device 10 may include patterns, which are traces according to the shape and deposition process of the bank structure BNS. The patterns may be formed simultaneously with the capping layers CPL1, CPL2, and CPL3 and the light emitting layers EL1, EL2, and EL3 and the cathode electrodes CE1, CE2, and CE3 of the light emitting elements ED1, ED2, and ED3, and may remain on the bank structure BNS. Portions of the auxiliary common electrodes SPL1, SPL2, and SPL3 disposed on the bank structure BNS may be disposed to cover the patterns. Hereinafter, structures of the light emitting layers EL1, EL2, and EL3 and the cathode electrodes CE1, CE2, and CE3 and the patterns will be described.

The display device 10 according to an embodiment may include capping patterns CLP1, CLP2, and CLP3 including the same material as the capping layers CPL1, CPL2, and CPL3 and disposed on the bank structure BNS. In the process of forming the capping layers CPL1, CPL2, and CPL3, a portion of the material forming the capping layers CPL1, CPL2, and CPL3 may be formed on the bank structure BNS as well as on the openings OPE1, OPE2, and OPE3 of the bank structure BNS and may to remain as a pattern. The capping patterns CLP1, CLP2, and CLP3 may also be in contact with the auxiliary common electrodes SPL1, SPL2, and SPL3 to form the common electrode layer.

For example, the display device 10 may include the capping patterns CLP1, CLP2, and CLP3 disposed on the bank structure BNS. The capping patterns CLP1, CLP2, and CLP3 may include a first capping pattern CLP1, a second capping pattern CLP2, and a third capping pattern CLP3 disposed on the second bank layer BN2 of the bank structure BNS.

Each of the first to third capping patterns CLP1, CLP2, and CLP3 may include the same material as the first to third capping layers CPL1, CPL2, and CPL3 disposed on the dummy pattern DMP. Each of the first to third capping patterns CLP1, CLP2, and CLP3 may be formed in the same process as the first to third capping layers CPL1, CPL2, and CPL3 including the same material.

The first to third capping patterns CLP1, CLP2, and CLP3 may be directly disposed on the second bank layer BN2 of the bank structure BNS. The first to third capping patterns CLP1, CLP2, and CLP3 may be disposed adjacent to the light emitting areas EA1, EA2, and EA3, respectively. For example, the first capping pattern CLP1 may be disposed on the second bank layer BN2 around the first light emitting area EA1 or the first opening OPE1. The second capping pattern CLP2 may be disposed on the second bank layer BN2 around the second light emitting area EA2 or the second opening OPE2, and the third capping pattern CLP3 may be disposed on the second bank layer BN2 around the third light emitting area EA3 or the third opening OPE3.

The display device 10 may include organic patterns ELP1, ELP2, and ELP3 including the same material as the light emitting layers EL1, EL2, and EL3 and disposed on the bank structure BNS. Since the light emitting layers EL1, EL2, and EL3 are formed through a process of depositing a material on the entire surface of the display device 10, the material forming the light emitting layers EL1, EL2, and EL3 may be deposited on the bank structure BNS as well as on the openings OPE1, OPE2, and OPE3 of the bank structure BNS.

For example, the display device 10 may include the organic patterns ELP1, ELP2, and ELP3 disposed on the bank structure BNS. The organic patterns ELP1, ELP2, and ELP3 may include a first organic pattern ELP1, a second organic pattern ELP2, and a third organic pattern ELP3 disposed on the second bank layer BN2 of the bank structure BNS.

The first organic pattern ELP1 may include the same material as the first light emitting layer EL1 of the first light emitting element ED1. The second organic pattern ELP2 may include the same material as the second light emitting layer EL2 of the second light emitting element ED2, and the third organic pattern ELP3 may include the same material as the third light emitting layer EL3 of the third light emitting element ED3. Each of the organic patterns ELP1, ELP2, and ELP3 may be formed in the same process as the light emitting layers EL1, EL2, and EL3 including the same material.

The first organic pattern ELP1, the second organic pattern ELP2, and the third organic pattern ELP3 may be disposed on the first to third capping patterns CLP1, CLP2, and CLP3, respectively. An arrangement relationship between the first to third organic patterns ELP1, ELP2, and ELP3 and the first to third capping patterns CLP1, CLP2, and CLP3 may be the same as an arrangement relationship between the capping layers CPL1, CPL2, and CPL3 and the light emitting layers EL1, EL2, and EL3. Similar to the capping patterns CLP1, CLP2, and CLP3, the organic patterns ELP1, ELP2, and ELP3 may be traces formed by being disconnected from the light emitting layers EL1, EL2, and EL3 as the bank structure BNS includes the tip.

The display device 10 may include electrode patterns CEP1, CEP2, and CEP3 including the same material as the cathode electrodes CE1, CE2, and CE3 and disposed on the bank structure BNS. The electrode patterns CEP1, CEP2, and CEP3 may include a first electrode pattern CEP1, a second electrode pattern CEP2, and a third electrode pattern CEP3 disposed on the second bank layer BN2 of the bank structure BNS.

For example, the first electrode pattern CEP1, the second electrode pattern CEP2, and the third electrode pattern CEP3 may be directly disposed on the first organic pattern ELP1, the second organic pattern ELP2, and the third organic pattern ELP3, respectively. An arrangement relationship between the electrode patterns CEP1, CEP2, and CEP3 and the organic patterns ELP1, ELP2, and ELP3 may be the same as an arrangement relationship between the light emitting layers EL1, EL2, and EL3 and the cathode electrodes CE1, CE2, and CE3 of the light emitting elements ED1, ED2, and ED3. The electrode patterns CEP1, CPE2, and CEP3 may be traces formed in case that the deposited material is disconnected from the cathode electrodes CE1, CE2, and CE3 as the bank structure BNS includes the tip. In the display device 10, the cathode electrodes CE1, CE2, and CE3 may be individually formed in different areas by the tip of the bank structure BNS even in a deposition process that does not use the mask.

The auxiliary common electrodes SPL1, SPL2, and SPL3 may cover the above-described patterns on the bank structure BNS. The first auxiliary common electrode SPL1 may be disposed along an outer surface of the bank structure BNS, and may cover the first capping pattern CLP1, the first organic pattern ELP1, and the first electrode pattern CEP1 disposed on the second bank layer BN2. The first auxiliary common electrode SPL1 may be directly disposed on the first electrode pattern CEP1 and may be in contact with side surfaces of the first capping pattern CLP1 and the first organic pattern ELP1. Even in the case of the second auxiliary common electrode SPL2 and the third auxiliary common electrode SPL3, the arrangement and contact relationship with the organic patterns ELP1, ELP2, and ELP3 and the electrode patterns CEP1, CEP2, and CEP3 may be the same.

However, on the second bank layer BN2, different capping patterns CLP1, CLP2, and CLP3, organic patterns ELP1, ELP2, and ELP3, and electrode patterns CEP1, CEP2, and CEP3 may be spaced apart from each other, and side surfaces spaced apart from each other may be exposed. This may be an area from which the patterns disposed on the second bank layer BN2 are removed after the auxiliary common electrodes SPL1, SPL2, and SPL3 and inorganic layers TL1, TL2, and TL3 of the first encapsulation layer TFE1 to be described later are formed.

The thin film encapsulation layer TFEL may be disposed on the light emitting elements ED1, ED2, and ED3 and the bank structure BNS, and may cover the light emitting elements ED1, ED2, and ED3 and the bank structure BNS. The thin film encapsulation layer TFEL may include at least one inorganic film to prevent oxygen or moisture from permeating into the light emitting element layer EML. The thin film encapsulation layer TFEL may include at least one organic film to protect the light emitting element layer EML from foreign substances such as dust.

In an embodiment, the thin film encapsulation layer TFEL may include a first encapsulation layer TFE1, a second encapsulation layer TFE2, and a third encapsulation layer TFE3 that are stacked on each other. The first encapsulation layer TFE1 and the third encapsulation layer TFE3 may be inorganic encapsulation layers, and the second encapsulation layer TFEL disposed therebetween may be an organic encapsulation layer.

Each of the first encapsulation layer TFE1 and the third encapsulation layer TFE3 may include one or more inorganic insulating materials. The inorganic insulating material may include aluminum oxide, titanium oxide, tantalum oxide, hafnium oxide, zinc oxide, silicon oxide, silicon nitride, and/or silicon oxynitride.

The second encapsulation layer TFE2 may include a polymer-based material. Examples of the polymer-based material may include an acrylic resin, an epoxy-based resin, polyimide, polyethylene, and/or the like. For example, the second encapsulation layer TFE2 may include an acrylic resin, for example, polymethyl methacrylate and/or polyacrylic acid. The second encapsulation layer TFE2 may be formed by curing a monomer or applying a polymer.

The first encapsulation layer TFE1 may be disposed on the light emitting elements ED1, ED2, and ED3, the patterns, and the bank structure BNS. The first encapsulation layer TFE1 may include a first inorganic layer TL1, a second inorganic layer TL2, and a third inorganic layer TL3 disposed to correspond to the different light emitting areas EA1, EA2, and EA3, respectively.

Each of the first inorganic layer TL1, the second inorganic layer TL2, and the third inorganic layer TL3 may include an inorganic insulating material to cover the light emitting elements ED1, ED2, and ED3. The first inorganic layer TL1, the second inorganic layer TL2, and the third inorganic layer TL3 may prevent the light emitting elements ED1, ED2, and ED3 from being damaged by external air, and may prevent the patterns disposed on the bank structure BNS from being peeled off during the process of fabricating the display device 10. In an embodiment, the first inorganic layer TL1, the second inorganic layer TL2, and the third inorganic layer TL3 may include aluminum oxide, titanium oxide, tantalum oxide, hafnium oxide, zinc oxide, silicon oxide, silicon nitride, and/or silicon oxynitride.

The first inorganic layer TL1, the second inorganic layer TL2, and the third inorganic layer TL3 may be disposed to cover the capping patterns CLP1, CLP2, and CLP3, the organic patterns ELP1, ELP2, and ELP3, the electrode patterns CEP1, CEP2, and CEP3, and the auxiliary common electrodes SPL1, SPL2, and SPL3. Since the first inorganic layer TL1, the second inorganic layer TL2, and the third inorganic layer TL3 may be formed through chemical vapor deposition (CVD) or atomic layer deposition (ALD), the first inorganic layer TL1, the second inorganic layer TL2, and the third inorganic layer TL3 may be formed with a uniform thickness along the step of the deposited layer. For example, the first inorganic layer TL1, the second inorganic layer TL2, and the third inorganic layer TL3 may form the thin films even on the lower portion of the undercut formed by the tip of the bank structure BNS.

The first inorganic layer TL1 may be disposed on the first auxiliary common electrode SPL1. The first inorganic layer TL1 may be disposed along inner sidewalls of the first auxiliary common electrode SPL1 and the first opening OPE1 to cover the first auxiliary common electrode SPL1 and the first opening OPE1, and may also be disposed to cover the first capping pattern CLP1, the first organic pattern ELP1, the first electrode pattern CEP1, and the first auxiliary common electrode SPL1. However, the first inorganic layer TL1 may not overlap the second opening OPE2 and the third opening OPE3 and may be disposed only on the first opening OPE1 and the bank structure BNS around the first opening OPE1.

The second inorganic layer TL2 may be disposed on the second auxiliary common electrode SPL2. The second inorganic layer TL2 may be disposed along inner sidewalls of the second auxiliary common electrode SPL2 and the second opening OPE2 to cover the second auxiliary common electrode SPL2 and the second opening OPE2, and may also be disposed to cover the second capping pattern CLP2, the second organic pattern ELP2, the second electrode pattern CEP2, and the second auxiliary common electrode SPL2. However, the second inorganic layer TL2 may not overlap the first opening OPE1 and the third opening OPE3 and may be disposed only on the second opening OPE2 and the bank structure BNS around the second opening OPE2.

The third inorganic layer TL3 may be disposed on the third auxiliary common electrode SPL3. The third inorganic layer TL3 may be disposed along inner sidewalls of the third auxiliary common electrode SPL3 and the third opening OPE3 to cover the third auxiliary common electrode SPL3 and the third opening OPE3, and may also be disposed to cover the third capping pattern CLP3, the third organic pattern ELP3, the third electrode pattern CEP3, and the third auxiliary common electrode SPL3. However, the third inorganic layer TL3 may not overlap the first opening OPE1 and the second opening OPE2 and may be disposed only on the third opening OPE3 and the bank structure BNS around the third opening OPE3.

The first inorganic layer TL1 may be formed after the first auxiliary common electrode SPL1 is formed, the second inorganic layer TL2 may be formed after the second auxiliary common electrode SPL2 is formed, and the third inorganic layer TL3 may be formed after the third auxiliary common electrode SPL3 is formed. Accordingly, the first to third inorganic layers TL1, TL2, and TL3 may be disposed to cover the different auxiliary common electrodes SPL1, SPL2, and SPL3, respectively. In plan view, each of the first inorganic layer TL1, the second inorganic layer TL2, and the third inorganic layer TL3 may have a larger area than the openings OPE1, OPE2, and OPE3 of the bank structure BNS. The first inorganic layer TL1, the second inorganic layer TL2, and the third inorganic layer TL3 may be disposed to be spaced apart from each other on the bank structure BNS. Accordingly, a portion of the second bank layer BN2 of the bank structure BNS may not overlap the inorganic layers TL1, TL2, and TL3, and a portion of the upper surface thereof may be exposed without being covered by the inorganic layers TL1, TL2, and TL3. A portion of the second bank layer BN2 may be in direct contact with a second encapsulation layer TFE2 of the thin film encapsulation layer TFEL, which will be described later.

The touch sensing layer TSU may be disposed on the encapsulation layer TFEL. The touch sensing layer TSU may include a first touch insulating layer SIL1, a second touch insulating layer SIL2, a touch electrode TEL, and a third touch insulating layer SIL3.

The first touch insulating layer SIL1 may be disposed on the encapsulation layer TFEL. The first touch insulating layer SIL1 may have insulation and optical functions. The first touch insulating layer SIL1 may include at least one inorganic film. Optionally, the first touch insulating layer SIL1 may be omitted.

The second touch insulating layer SIL2 may cover the first touch insulating layer SILL. Although not illustrated in the drawing, a touch electrode of another layer may be further disposed on the first touch insulating layer SIL1, and the second touch insulating layer SIL2 may cover such a touch electrode TEL. The second touch insulating layer SIL2 may have insulation and optical functions. For example, the second touch insulating layer SIL2 may be an inorganic film including at least one of a silicon nitride layer, a silicon oxy nitride layer, a silicon oxide layer, a titanium oxide layer, and an aluminum oxide layer.

A portion of the touch electrode TEL may be disposed on the second touch insulating layer SIL2. Each of the touch electrodes TEL may not overlap the first to third light emitting areas EA1, EA2, and EA3. Each of the touch electrodes TEL may be formed as a single layer made of molybdenum (Mo), titanium (Ti), copper (Cu), aluminum (Al), and/or indium tin oxide (ITO), or be formed as a stacked structure (Ti/Al/Ti) of aluminum and titanium, a stacked structure (ITO/Al/ITO) of aluminum and ITO, an APC alloy, and/or a stacked structure (ITO/APC/ITO) of an APC alloy and ITO.

The third touch insulating layer SIL3 may cover the touch electrode TEL and the second touch insulating layer SIL2. The third touch insulating layer SIL3 may have insulation and optical functions. The third touch insulating layer SIL3 may be made of the materials illustrated in the second touch insulating layer SIL2.

The light blocking layer BM may be disposed on the touch sensing layer TSU. The light blocking layer BM may include opening holes OPT1, OPT2, and OPT3 disposed to overlap the light emitting areas EA1, EA2, and EA3. For example, the first opening hole OPT1 may be disposed to overlap the first light emitting area EA1. The second opening hole OPT2 may be disposed to overlap the second light emitting area EA2, and the third opening hole OPT3 may be disposed to overlap the third light emitting area EA3. The area or size of each of the opening holes OPT1, OPT2, and OPT3 may be greater than that of the light emitting areas EA1, EA2, and EA3 defined by a bank structure BNS. As the opening holes OPT1, OPT2, and OPT3 of the light blocking layer BM are formed to be greater than the light emitting areas EA1, EA2, and EA3, light emitted from the light emitting areas EA1, EA2, and EA3 may be visually recognized by a user not only from a front side of the display device 10 but also from a side surface thereof.

The light blocking layer BM may include a light absorbing material. For example, the light blocking layer BM may include an inorganic black pigment or an organic black pigment. The inorganic black pigment may be carbon black, and the organic black pigment may include at least one of lactam black, perylene black, and aniline black, but is not limited thereto. The light blocking layer BM may prevent visible light from permeating and mixing colors between the first to third light emitting areas EA1, EA2, and EA3, thereby improving a color reproduction rate of the display device 10.

The display device 10 may include color filters CF1, CF2, and CF3 disposed on the light emitting areas EA1, EA2, and EA3. Each of the color filters CF1, CF2, and CF3 may be disposed to correspond to the light emitting areas EA1, EA2, and EA3. For example, the color filters CF1, CF2, and CF3 may be disposed on the light blocking layer BM including the opening holes OPT1, OPT2, and OPT3 disposed to correspond to the light emitting areas EA1, EA2, and EA3. The hole of the light blocking layer may be formed to overlap the light emitting areas EA1, EA2, and EA3 or the openings of the bank structures BNS, and may form a light output area from which light emitted from the light emitting areas EA1, EA2, and EA3 is emitted. Each of the color filters CF1, CF2, and CF3 may have a larger area than the hole of the light blocking layer BM, and may completely cover the light output area formed by the hole.

The color filters CF1, CF2, and CF3 may include a first color filter CF1, a second color filter CF2, and a third color filter CF3 disposed to correspond to different light emitting areas EA1, EA2, and EA3, respectively. The color filters CF1, CF2, and CF3 may include a colorant such as a dye or pigment that absorbs light in a wavelength band other than light in a specific wavelength band, and may be disposed to correspond to the colors of light emitted from the light emitting areas EA1, EA2, and EA3. For example, the first color filter CF1 may be a red color filter that is disposed to overlap the first light emitting area EA1 and transmits only first light in red. The second color filter CF2 may be a green color filter that is disposed to overlap the second light emitting area EA2 and transmits only second light in green, and the third color filter CF3 may be a blue color filter that is disposed to overlap the third light emitting area EA3 and transmits only third light in blue.

The color filters CF1, CF2, and CF3 may be spaced apart from other adjacent color filters CF1, CF2, and CF3 on the light blocking layer BM. The color filters CF1, CF2, and CF3 may cover the opening holes OPT1, OPT2, and OPT3 of the light blocking layer BM, respectively, and may have an area larger than the hole, but may have an area sufficient to be spaced apart from the other color filters CF1, CF2, and CF3 on the light blocking layer BM. However, the disclosure is not limited thereto. The color filters CF1, CF2, and CF3 may be disposed to partially overlap other adjacent color filters CF1, CF2, and CF3. The different color filters CF1, CF2, and CF3 may be areas that overlap the light emitting areas EA1, EA2, and EA3, and may overlap each other on the light blocking layer BM, which will be described later. In the display device 10, as the color filters CF1, CF2, and CF3 are disposed to overlap each other, intensity of reflected light caused by external light may be reduced. Furthermore, the color of light reflected by external light may also be controlled by adjusting the arrangement, shape, and area of the color filters CF1, CF2, and CF3 in plan view.

The color filters CF1, CF2, and CF3 of the color filter layer CFL may be disposed on the light blocking layer BM. The different color filters CF1, CF2, and CF3 may be disposed to correspond to the different light emitting areas EA1, EA2, and EA3 or the openings OPE1, OPE2, and OPE3, and the opening holes OPT1, OPT2, and OPT3 of the light blocking layer BM, respectively. For example, the first color filter CF1 may be disposed to correspond to the first light emitting area EA1, the second color filter CF2 may be disposed to correspond to the second light emitting area EA2, and the third color filter CF3 may be disposed to correspond to the third light emitting area EA3. The first color filter CF1 may be disposed in the first opening hole OPT1 of the light blocking layer BM, the second color filter CF2 may be disposed in the second opening hole OPT2 of the light blocking layer BM, and the third color filter CF3 may be disposed in the third opening hole OPT3 of the light blocking layer BM. Each of the color filters CF1, CF2, and CF3 may be disposed to have a larger area in plan view than the opening holes OPT1, OPT2, and OPT3 of the light blocking layer BM, and some of the color filters CF1, CF2, and CF3 may be directly disposed on the light blocking layer BM.

An overcoat layer OC may be disposed on the color filters CF1, CF2, and CF3 to planarize upper ends of the color filters CF1, CF2, and CF3. The overcoat layer OC may be a colorless light-transmitting layer having no color in a visible light band. For example, the overcoat layer OC may include a colorless light-transmitting organic material such as an acryl-based resin.

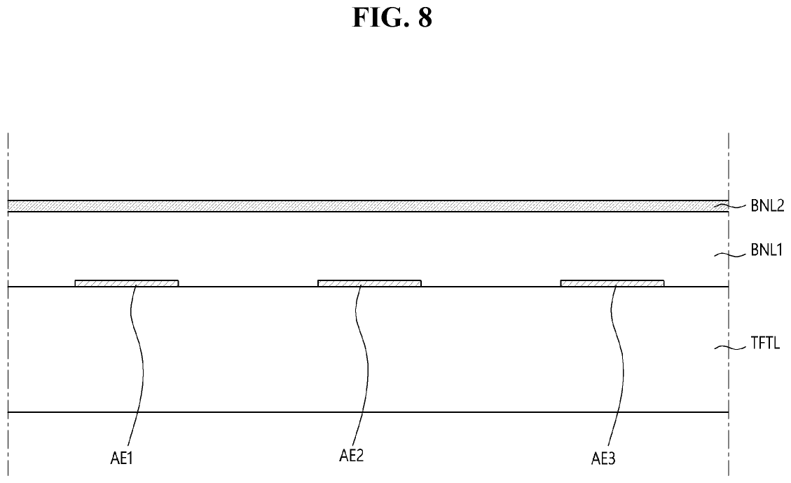

Hereinafter, a process of fabricating the display device 10 according to an embodiment will be described with reference to FIGS. 8-19.

FIGS. 8 to 19 are schematic cross-sectional views sequentially illustrating a display area during a process of fabricating a display device according to an embodiment.

FIGS. 8 to 19 schematically illustrate a process of forming the bank structure BNS and the light emitting elements ED1, ED2, and ED3 as the light emitting element layer EML of the display device 10. Hereinafter, a description of a formation process of each layer in the process of fabricating the display device 10 will be omitted, and a formation order of each layer will be described.

Referring to FIG. 8, anode electrodes AE1, AE2, and AE3 and bank material layers BNL1 and BNL2 may be formed on the thin film transistor layer TFTL.

Although not illustrated in the drawings, the thin film transistor layer TFTL may be disposed on the substrate SUB, and a structure of the thin film transistor TFTL may be the same as that described above with reference to FIG. 6. A detailed description thereof is omitted.

The anode electrodes AE1, AE2, and AE3 may be disposed to be spaced apart from each other on the thin film transistor layer TFTL. The anode electrodes AE1, AE2, and AE3 may include a first anode electrode AE1, a second anode electrode AE2, and a third anode electrode AE3 of the different light emitting elements ED1, ED2, and ED3. The first to third anode electrodes AE1, AE2, and AE3 may be disposed to be spaced apart from each other on the thin film transistor layer TFTL.

Bank material layers BNL1 and BNL2 may be disposed on the anode electrodes AE1, AE2, and AE3 and the thin film transistor layer TFTL. The bank material layers BNL1 and BNL2 may be disposed to entirely cover the anode electrodes AE1, AE2, and AE3. The bank material layers BNL1 and BNL2 may include a first bank material layer BNL1 and a second bank material layer BNL2 stacked on each other. The first bank material layer BNL1 may be directly disposed on the anode electrodes AE1, AE2, and AE3 and the thin film transistor layer TFTL, and the second bank material layer BNL2 may be disposed on the first bank material layer BNL1. The bank material layers BNL1 and BNL2 may be partially etched in a subsequent process to form bank layers BN1 and BN2 and a dummy pattern DMP of the bank structure BNS illustrated in FIG. 6, respectively. The first bank material layer BNL1 and the second bank material layer BNL2 may include different materials, respectively, to form the first bank layer BN1 or the dummy pattern DMP and the second bank layer BN2.

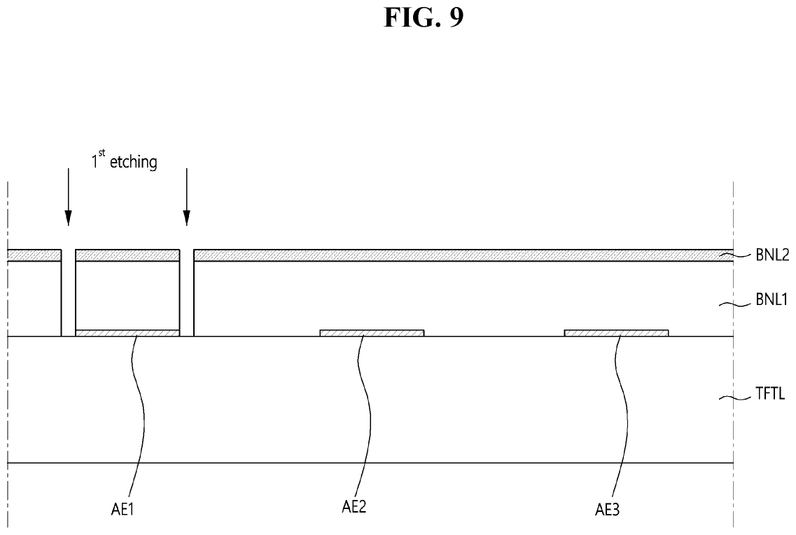

Referring to FIG. 9, the light emitting areas EA1, EA2, and EA3 may be distinguished from the bank structure BNS area by performing a first etching process of etching portions of the bank material layers BNL1 and BNL2 In this process, portions of the bank material layers BNL1 and BNL2 disposed on the first anode electrode AE1 and other portions thereof may be distinguished. In a subsequent process, the bank material layers BNL1 and BNL2 disposed on the first anode electrode AE1 may be etched to form the dummy pattern DMP and other portions thereof may form the bank structure BNS. It is illustrated in the drawing that only portions of the bank material layers BNL1 and BNL2 disposed on the first anode electrode AE1 are separated. During the process of fabricating the display device 10, the first etching process may be repeated several times so that portions disposed on the second anode electrode AE2 and the third anode electrode AE3 may also be distinguished.

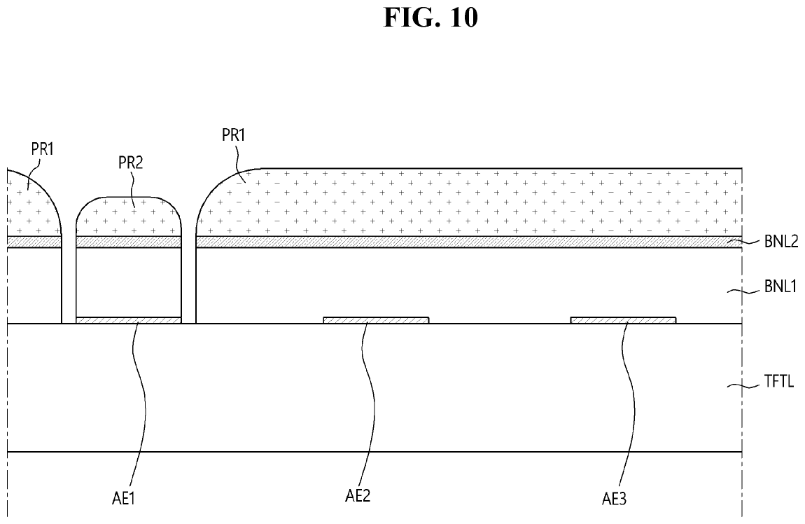

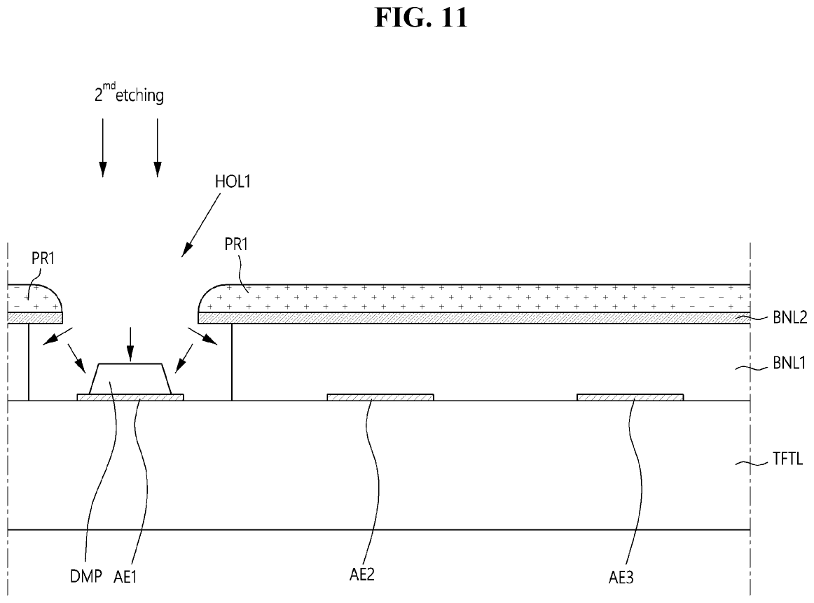

Referring to FIGS. 10 and 11, photoresists PR1 and PR2 may be formed on the bank material layers BNL1 and BNL2, and a second etching process of etching some of the bank material layers BNL1 and BNL2 using the photoresists PR1 and PR2 as a mask may be performed to form a first hole HOL1.

The photoresists PR1 and PR2 may be disposed to be spaced apart from each other on the bank material layers BNL1 and BNL2. A first photoresist PR1 may be formed so as not to overlap the first anode electrode AE1, and a second photoresist PR2 may be formed to overlap the first anode electrode AE1. The first photoresist PR1 and the second photoresist PR2 may have different thicknesses. In the second etching process, portions where the first photoresist PR1 and the second photoresist PR2 are disposed may be etched into different shapes.

In an embodiment, the second etching process may be performed as an isotropic etching process. In the second etching process, the bank material layers BNL1 and BNL2 including different materials may be etched differently depending on the etching rate or the thicknesses of the photoresists PR1 and PR2. For example, the etching rate of the portions of the bank material layers BNL1 and BNL2 overlapping the second photoresist PR2 may be faster than that of other portions. Accordingly, in the portions of the bank material layers BNL1 and BNL2 overlapping the second photoresist PR2, the second bank material layer BNL2 may be completely removed, and the first bank material layer BNL1 may also be reduced in thickness. The dummy pattern DMP formed by etching the first bank material layer BNL1 may be formed on the first anode electrode AE1. The second etching process may be performed until a portion of the first anode electrode AE1 is exposed because the first bank material layer BNL1 disposed on the first anode electrode AE1 has a smaller area in plan view than the first anode electrode AE1.

In the portions of the bank material layers BNL1 and BNL2 overlapping the first photoresist PR1, the etching rate of the first bank material layer BNL1 may be faster than that of the second bank material layer BNL2. Accordingly, in the portion of the bank material layers BNL1 and BNL2 overlapping the first photoresist PR1, the second bank material layer BNL2 may be hardly etched, and the first bank material layer BNL1 on the lower portion of the second bank material layer BNL2 may be etched by isotropic etching. In the second etching process, a side surface of the first bank material layer BNL1 may be depressed inward more than the second bank material layer BNL2, and a tip may be formed in the second bank material layer BNL2.

The first hole HOL1 formed in the second etching process may be formed to overlap the first anode electrode AE1, and may form the first opening OPE1 of the bank structure BNS.

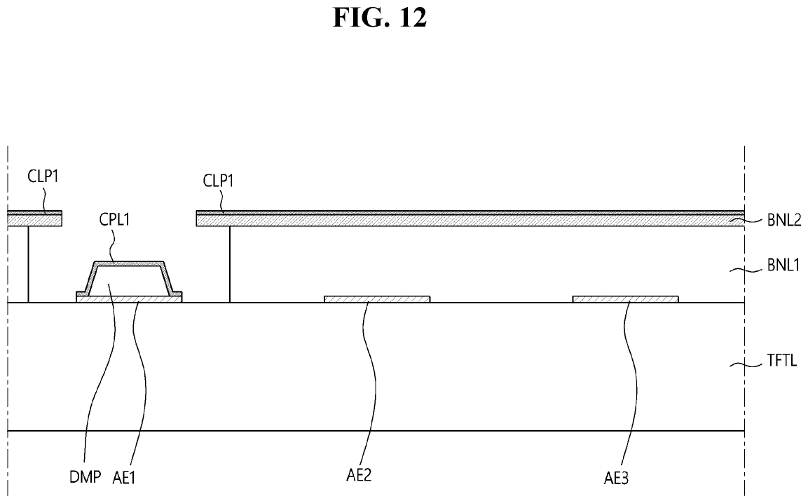

Referring to FIG. 12, a first capping layer CPL1 and a first capping pattern CLP1 may be formed on the dummy pattern DMP and the second bank material layer BNL2. The first capping layer CPL1 and the first capping pattern CLP1 may be formed through a mask process. The first capping layer CPL1 may be formed to cover the dummy pattern DMP, and a portion thereof may be directly disposed on the first anode electrode AE1. The first capping pattern CLP1 may be disposed on the second bank material layer BNL2 and may be formed to be separated from the first capping layer CPL1.

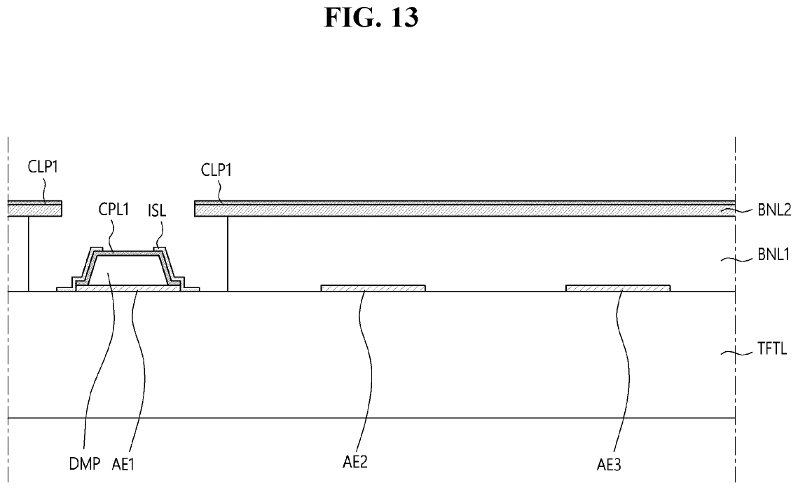

Referring to FIG. 13, an inorganic insulating layer ISL may be formed on the first capping layer CPL1. The inorganic insulating layer ISL may be formed to cover the first capping layer CPL1 but to expose a portion of an upper surface of the first capping layer CPL1. The inorganic insulating layer ISL may also be formed through a mask process and may be patterned to completely cover a portion of the first capping layer CPL1 and a side surface of the first anode electrode AE1.

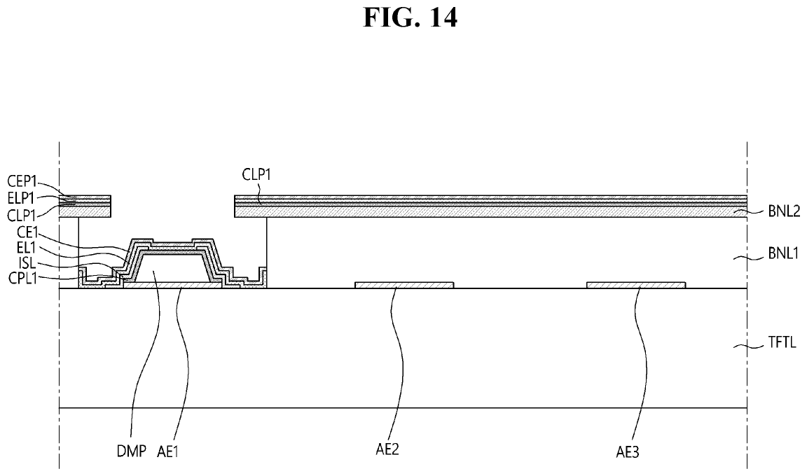

Referring to FIG. 14, a first light emitting element ED1 may be formed by depositing a first light emitting layer EL1 and a first cathode electrode CE1 on the first capping layer CPL1. The first light emitting layer EL1 and the first cathode electrode CE1 may be formed in the first opening OPE1, and in the deposition process, the materials forming the first light emitting layer EL1 and the first cathode electrode CE1 may also be deposited on the second bank material layers BNL2 to form patterns. For example, some of the materials may be deposited on the first capping pattern CLP1 of the second bank material layer BNL2 to form a first organic pattern ELP1 and a first electrode pattern CEP1. The descriptions of structures of the first light emitting layer EL1, the first cathode electrode CE1, the first organic pattern ELP1, and the first electrode pattern CEP1 may be the same as those described above.

The first light emitting layer EL1 and the first cathode electrode CE1 may be formed through a deposition process. The material may not be smoothly deposited in the first opening OPE1 due to the tip of the second bank material layer BNL2. However, since the materials of the first light emitting layer EL1 and the first cathode electrode CE1 are deposited in an inclined direction rather than a direction perpendicular to the upper surface of the substrate, the deposition may also be performed on an area of the first bank material layer BNL1 covered by the tip.

For example, the deposition process of forming the first light emitting layer EL1 may be performed such that the materials are deposited in a direction that is not perpendicular to the upper surface of the first anode electrode AE1, for example, in a direction inclined at a first angle. In an embodiment, in the process of forming the light emitting layers EL1, EL2, and EL3, the material deposition may be performed at an angle of 45° to 50° from the upper surfaces of the anode electrodes AE1, AE2, and AE3. The first light emitting layer EL1 may also be formed in a space between the first anode electrode AE1 and the first bank structure BNS1. For example, the first light emitting layer EL1 may be an area covered by the tip and may be partially disposed on the side surface of the first bank material layer BNL1.

The deposition process of forming the first cathode electrode CE1 may be performed such that the materials are deposited in a direction that is not perpendicular to the upper surface of the first anode electrode AE1, for example, in a direction inclined at a second angle. In an embodiment, in the process of forming the cathode electrodes CE1, CE2, and CE3, the deposition of the material may be performed to be inclined at an angle of 30° or less from the upper surfaces of the anode electrodes AE1, AE2, and AE3. The first cathode electrode CE1 may be disposed on the first light emitting layer EL1 and may also be formed in an area covered by the tip of the second bank material layer BNL2. For example, the first cathode electrode CE1 may be an area covered by the tip and may be partially disposed on the side surface of the first bank material layer BNL1.

Compared to the deposition process of forming the light emitting layers EL1, EL2, and EL3, the deposition process of forming the cathode electrodes CE1, CE2, and CE3 may be performed to be inclined in a relatively more horizontal direction. Accordingly, the area of the cathode electrodes CE1, CE2, and CE3 in contact with the side surface of the first bank material layer BNL1 or the first bank layer BN1 may be greater than that of the light emitting layers EL1, EL2, and EL3. In other embodiments, the cathode electrodes CE1, CE2, and CE3 may be deposited to a higher position on the side of the first bank material layer BNL1 or the first bank layer BN1 than the light emitting layers EL1, EL2, and EL3. However, as the first bank material layer BNL1 includes an insulating material, the light emitting layers EL1, EL2, and EL3 and the cathode electrodes CE1, CE2, and CE3 may not be electrically connected to the first bank material layer BNL1.

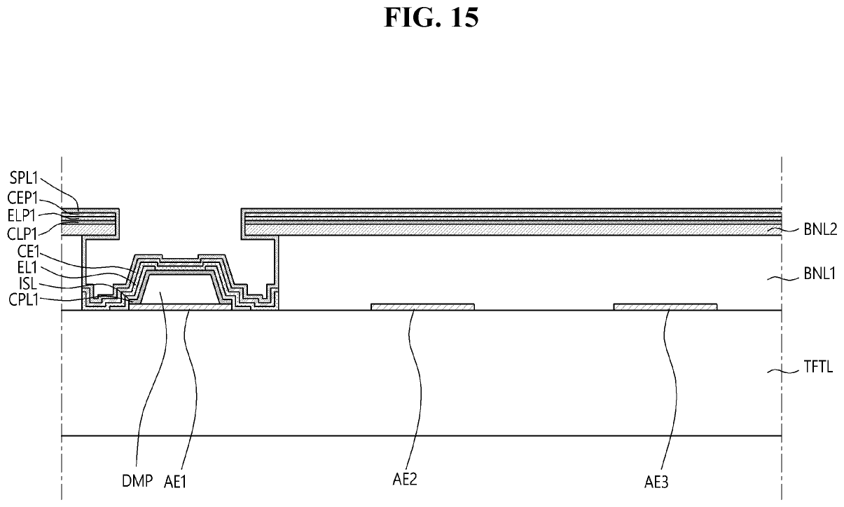

Referring to FIG. 15, a first auxiliary common electrode SPL1 may be formed on the first cathode electrode CE1 and the first electrode pattern CEP1. Unlike the light emitting layers EL1, EL2, and EL3 and the cathode electrodes CE1, CE2, and CE3, the first auxiliary common electrode SPL1 may be formed by a chemical vapor deposition (CVD) process or an atomic layer deposition (ALD) process, and may form a uniform film regardless of a step of the deposited portion. The first auxiliary common electrode SPL1 may be formed to completely cover outer surfaces of the first light emitting element ED1, the bank material layers BNL1 and BNL2, and the patterns. In particular, the first auxiliary common electrode SPL1 may be deposited on the lower portion and side surface of the tip of the second bank material layer BNL2, and may be in contact with the second bank material layer BNL2 and the first capping pattern CLP1.

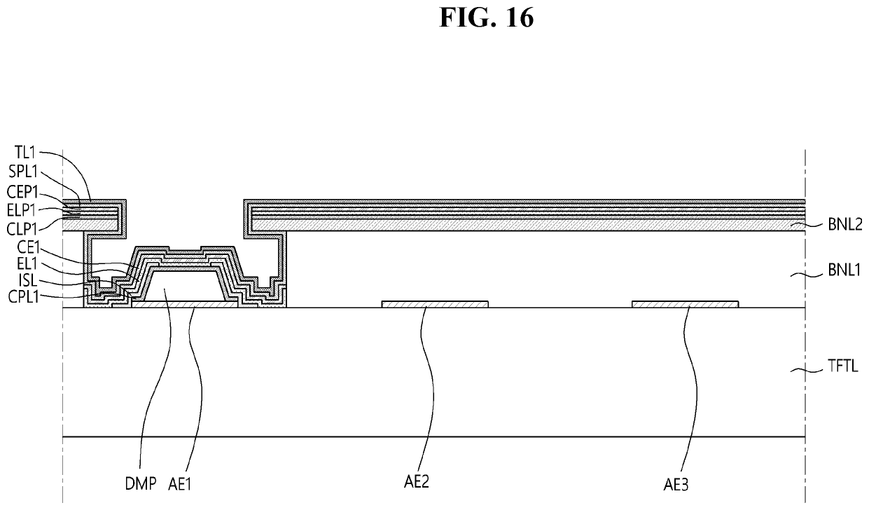

Referring to FIG. 16, a first inorganic layer TL1 covering the first light emitting element ED1 and the first auxiliary common electrode SPL1 may be formed. Unlike the light emitting layers EL1, EL2, and EL3 and the cathode electrodes CE1, CE2, and CE3, the first inorganic layer TL1 may be formed by a chemical vapor deposition (CVD) process, and may form a uniform film regardless of a step of the deposited portion. The first inorganic layer TL1 may be formed to completely cover outer surfaces of the first light emitting element ED1, the bank material layers BNL1 and BNL2, and the capping layers CPL. In particular, the first inorganic layer TL1 may also be deposited on a lower portion of the tip of the second bank material layer BNL2.

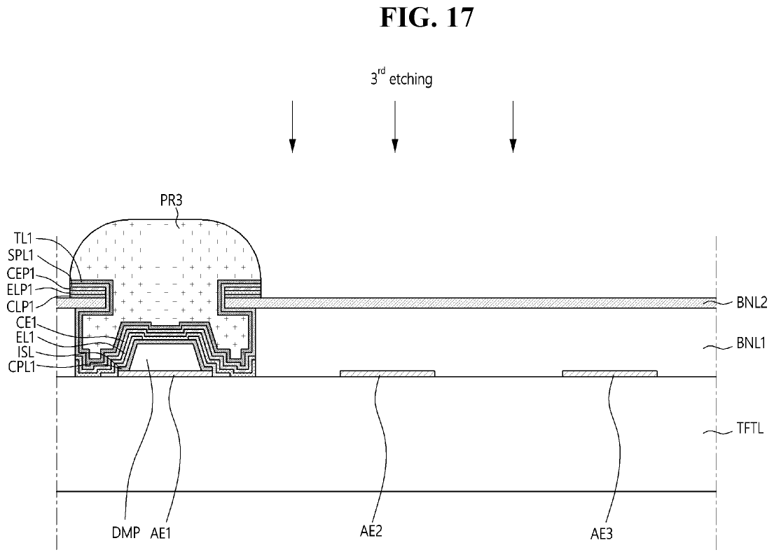

Referring to FIG. 17, a third photoresist PR3 may be formed on the first inorganic layer TL1, and a third etching process of partially removing the first capping pattern CLP1, the first organic pattern ELP1, the first electrode pattern CEP1, the first auxiliary common electrode SPL1, and the first inorganic layer TL1 disposed on the bank material layers BNL1 and BNL2 is performed.

In this process, the third photoresist PR3 may be disposed on the first opening OPE1 to overlap the first light emitting element ED1. All of the first capping pattern CLP1, the first organic pattern ELP1, the first electrode pattern CEP1, the first auxiliary common electrode SPL1, and the first inorganic layer TL1 disposed on the bank material layers BNL1 and BNL2 may be removed except around the first opening OPE1 or the first light emitting element ED1. In this process, an area of the second bank material layer BNL2 except around the first opening OPE1 or the first light emitting element ED1 may be exposed. In an embodiment, the third etching process may be performed as a dry etching process using a fluorine (F)-based etchant.

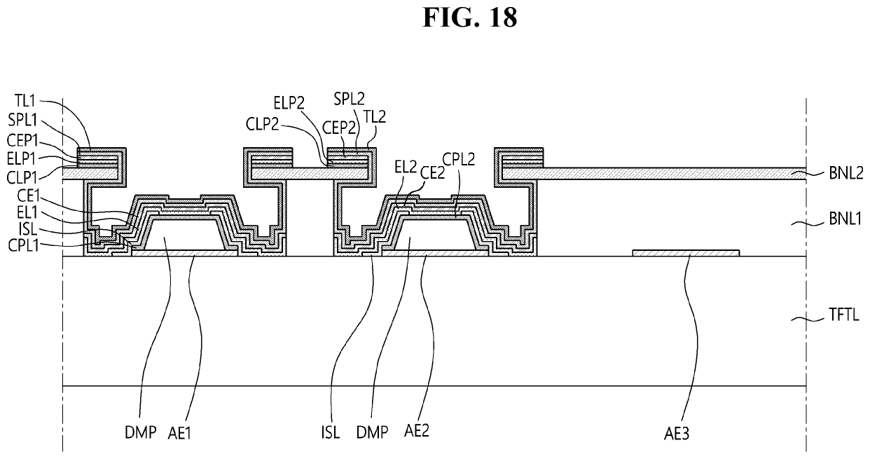

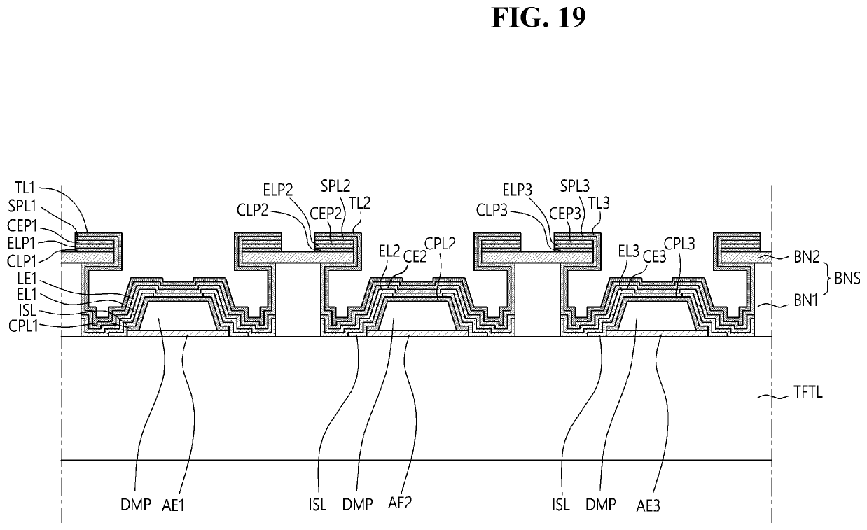

Through the above-described process, the first light emitting element ED1, the first auxiliary common electrode SPL1, and the first inorganic layer TL1 may be formed. Referring to FIGS. 18 and 19, by repeating the processes similar to those described above, a second light emitting element ED2, a third light emitting element ED3, second and third capping patterns CLP2 and CLP3, second and third organic patterns ELP2 and ELP3, second and third electrode patterns CEP2 and CEP3, a second inorganic layer TL2 and a third inorganic layer TL3, and a second auxiliary common electrode SPL2 and a third auxiliary common electrode SPL3 may be formed.

Although not illustrated in the drawing, a thin film encapsulation layer TFEL may be formed by forming a second encapsulation layer TFE2 and a third encapsulation layer TFE3 on the first encapsulation layers TFE1 and the bank structure BNS, and a touch sensing layer TSU, a light blocking layer BM, a color filter layer CFL, and an overcoat layer OC may be formed, thereby fabricating the display device 10.

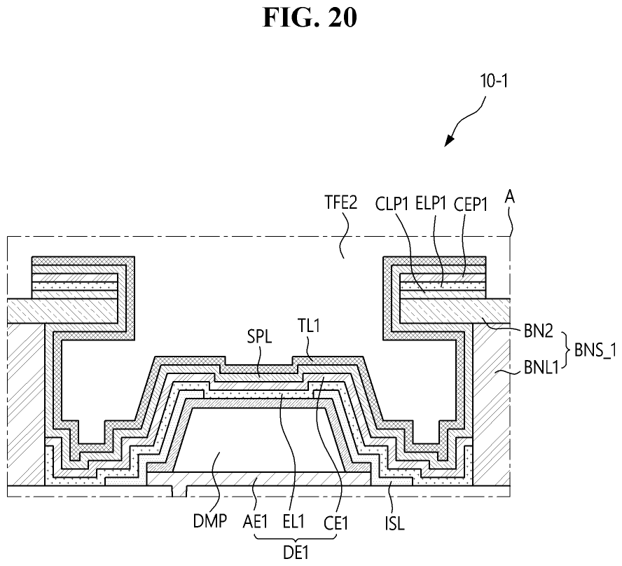

FIG. 20 is a schematic cross-sectional view illustrating a portion of a display device according to another embodiment.

Referring to FIG. 20, in a display device 10-1, a first bank layer BNL1 of the bank structure BNS_1 may include a metal material. According to an embodiment, the first bank layer BNL1 and the second bank layer BN2 may include different materials, and the bank structure BNS_1 may include a tip of the second bank layer BN2 protruding from the first bank layer BNL1 toward the openings OPE1, OPE2, and OPE3.

The shape of the sidewall of the bank structure BNS_1 may be a structure formed due to a difference in etching rate in an etching process because the first bank layer BNL1 and the second bank layer BN2 include different materials. According to an embodiment, the second bank layer BN2 may include a material having a slower etching rate than the first bank layer BNL1, and in the process of forming the openings OPE1, OPE2, and OPE3 of the bank structure BNS_1, the first bank layer BNL1 may be further etched to form the undercut on the lower portion of the tip of the second bank layer BN2. In an embodiment, the first bank layer BNL1 may include a metal material having high electrical conductivity, and the second bank layer BN2 may include a metal material having low reflectivity. As an example, the first bank layer BNL1 may include aluminum (Al), and the second bank layer BN2 may include titanium (Ti). The bank structure BNS_1 may have a structure in which Al/Ti is stacked, and the tip may be formed in a Ti layer of the second bank layer BN2.

Side surfaces of the first bank layer BNL1 may be in contact with the light emitting layers EL1, EL2, and EL3 and the cathode electrodes CE1, CE2, and CE3. In case that a leakage current between the different light emitting elements ED1, ED2, and ED3 is controlled, the first bank layer BNL1 may form a common electrode layer together with the auxiliary common electrodes SPL1, SPL2, and SPL3 to further reduce electrical resistance.

In concluding the detailed description, those skilled in the art will appreciate that many variations and modifications can be made to the embodiments without substantially departing from the principles of the disclosure. Therefore, the disclosed embodiments are used in a generic and descriptive sense only and not for purposes of limitation.

What is claimed is:

1. A display device, comprising:
a plurality of anode electrodes disposed to be spaced apart from each other on a substrate;
a bank structure disposed on the substrate, disposed to surround the plurality of anode electrodes, and including a plurality of openings overlapping the plurality of anode electrodes;
a capping layer disposed on the plurality of anode electrodes, electrically connected to the plurality of anode electrodes, and having at least a portion spaced apart from the plurality of anode electrodes;
an inorganic insulating layer disposed on the capping layer within the plurality of openings of the bank structure and exposing a portion of an upper surface of the capping layer;
a plurality of light emitting layers each disposed on the capping layer and having a portion contacting a side surface of the bank structure;
a plurality of cathode electrodes disposed on the plurality of light emitting layers and having a portion contacting the side surface of the bank structure; and
a plurality of auxiliary common electrodes disposed on the plurality of cathode electrodes and having a portion disposed on the bank structure, wherein
the bank structure includes a first bank layer, and a second bank layer disposed on the first bank layer, including a material different from a material of the first bank layer, and including a tip protruding more than the first bank layer, and
the plurality of auxiliary common electrodes directly contact a side surface of the first bank layer and the second bank layer.

2. The display device of claim 1, further comprising:
a dummy pattern disposed between the plurality of anode electrodes and the capping layer.

3. The display device of claim 2, wherein
the first bank layer and the dummy pattern include a same material, and
the second bank layer includes a metal material.

4. The display device of claim 3, wherein
each of the dummy pattern and the first bank layer includes a transparent insulating material, and
the second bank layer includes titanium (Ti).

5. The display device of claim 2, wherein the dummy pattern has a thickness greater than a thickness of the plurality of anode electrodes but smaller than a thickness of the first bank layer.

6. The display device of claim 2, wherein
an area of the dummy pattern is smaller than an area of the plurality of anode electrodes, and
the capping layer directly contacts a portion of the plurality of anode electrodes that do not overlap the dummy pattern.

7. The display device of claim 2, wherein
the dummy pattern includes silicon oxide,
the first bank layer includes aluminum (Al), and
the second bank layer includes titanium (Ti).

8. The display device of claim 2, wherein the capping layer is disposed to cover an outer surface of the dummy pattern.

9. The display device of claim 1, wherein
a portion of the plurality of light emitting layers are directly disposed on the side surface of the first bank layer, and
the plurality of cathode electrodes cover the plurality of light emitting layers and a portion of the plurality of cathode electrodes are disposed directly on the side surface of the first bank layer.

10. The display device of claim 9, wherein the plurality of light emitting layers and the plurality of cathode electrodes are spaced apart from the second bank layer.

11. The display device of claim 1, wherein
the inorganic insulating layer is disposed to cover a side surface of the plurality of anode electrodes, and
at least a portion of the inorganic insulating layer is spaced apart from the second bank layer.

12. The display device of claim 1, wherein a portion of the plurality of auxiliary common electrodes are disposed on a lower portion of the tip of the second bank layer.

13. The display device of claim 1, wherein
the capping layer includes at least one of ITO, IZO, and ITZO, and
the plurality of auxiliary common electrodes include at least one of ITO, IZO, and TiN.

14. The display device of claim 1, further comprising:
a capping pattern disposed on the second bank layer and including a same material as the capping layer;
an organic pattern disposed on the capping pattern and including the same material as the plurality of light emitting layers; and
an electrode pattern disposed on the organic pattern and including the same material as the plurality of cathode electrodes,
wherein a portion of the plurality of auxiliary common electrodes are directly disposed on the electrode pattern.

15. The display device of claim 14, further comprising an inorganic layer disposed on the plurality of auxiliary common electrodes.

16. A method of fabricating a display device, the method comprising:
forming a plurality of anode electrodes spaced apart from each other on a substrate, a first bank material layer disposed on the plurality of anode electrodes and the substrate, and a second bank material layer;
forming a dummy pattern disposed on the plurality of anode electrodes by etching the first bank material layer and the second bank material layer, and forming an opening overlapping the plurality of anode electrodes;
forming a capping layer on the dummy pattern and forming an inorganic insulating layer disposed on the capping layer and exposing a portion of an upper surface of the capping layer;
forming a light emitting layer and a cathode electrode on the capping layer and the inorganic insulating layer;
forming an auxiliary common electrode disposed on the cathode electrode and disposed on a sidewall of the opening and the second bank material layer, and an inorganic layer disposed on the auxiliary common electrode; and
etching and removing a portion of the auxiliary common electrode and the inorganic layer disposed on the second bank material layer.

17. The method of claim 16, wherein in the forming of the opening, the second bank material layer has a tip protruding more than the first bank material layer.

18. The method of claim 16, wherein the light emitting layer and the cathode electrode partially contact the first bank material layer on the sidewall within the opening, and
the auxiliary common electrode directly contacts the first bank material layer and the second bank material layer.

19. The method of claim 16, wherein the dummy pattern includes a same material as the first bank material layer, and has a thickness smaller than a thickness of the first bank material layer and an area smaller than an area of the plurality of anode electrodes.

20. The method of claim 19, wherein the capping layer partially directly contacts the plurality of anode electrodes.
